(19) United States
(12) Patent Application Publication
(10) Pub. No.: US 2025/0286515 A1
(43) Pub. Date: Sep. 11, 2025

(54) POWER AMPLIFIER CIRCUIT

(71) Applicant: Murata Manufacturing Co., Ltd., Nagaokakyo-shi (JP)

(72) Inventors: Hisanori NAMIE, Nagaokakyo-shi (JP); Satoshi TANAKA, Nagaokakyo-shi (JP); Kiichiro TAKENAKA, Nagaokakyo-shi (JP); Fumio HARIMA, Nagaokakyo-shi (JP); Jun ENOMOTO, Nagaokakyo-shi (JP)

(21) Appl. No.: 19/215,414

(22) Filed: May 22, 2025

Related U.S. Application Data
(63) Continuation of application No. PCT/JP2023/042256, filed on Nov. 24, 2023.

(30) Foreign Application Priority Data
Nov. 25, 2022 (JP) 2022-188244

(51) Int. Cl. H03F 1/02; H03F 3/21

(52) U.S. Cl. CPC H03F 1/0288; H03F 3/211; H03F 2200/48

(57) ABSTRACT

A power amplifier circuit includes a carrier amplifier, which amplifies a first signal and outputs a first amplified signal from a first output terminal, a peak amplifier, which amplifies a second signal and outputs a second amplified signal from a second output terminal, a first inductor, connected to the first output terminal and a first node, a first capacitor, connected to the first node and the ground, a second inductor, connected to the second output terminal and a second node, a second capacitor, connected to the second node and the ground, a third inductor, connected to the first node and a third node connected to a load, and a third capacitor, connected to the second node and the third node.

### CROSS REFERENCE TO RELATED APPLICATION

This is a continuation of International Application No. PCT/JP2023/042256 filed on Nov. 24, 2023 which claims priority from Japanese Patent Application No. 2022-188244 filed on Nov. 25, 2022. The contents of these applications are incorporated herein by reference in their entireties.

### BACKGROUND ART

The present disclosure relates to a power amplifier circuit.

A Doherty amplifier includes a carrier amplifier and a peak amplifier (for example, see Patent Document 1). A semiconductor power amplifier includes a balanced amplifier (for example, see Patent Document 2).
Patent Document 1: Japanese Unexamined Patent Application Publication No. 2012-29239
Patent Document 2: Japanese Unexamined Patent Application Publication No. 2014-225791

### BRIEF SUMMARY

The Doherty amplifier described in Patent Document 1 achieves high efficiency, but needs a quarter-wave line, resulting in a large space required. In contrast, the balanced amplifier described in Patent Document 2 achieves resistance to fluctuations in load impedance, but has degraded efficiency. That is, it is difficult to obtain a power amplifier circuit which achieves both high efficiency and high resistance to fluctuations in load impedance.

The present disclosure is made in view of such a situation, and an object thereof is to provide a power amplifier circuit which achieves a reduction in size, high efficiency, and high resistance to fluctuations in load impedance.

A power amplifier circuit according to an aspect of the present disclosure includes a carrier amplifier, a peak amplifier, a first inductor, a first capacitor, a second inductor, a second capacitor, a third inductor, and a third capacitor. The carrier amplifier amplifies a first signal, and outputs a first amplified signal from a first output terminal. The peak amplifier amplifies a second signal different in phase from the first signal, and outputs a second amplified signal from a second output terminal. The first inductor has a first end connected to the first output terminal, and a second end connected to a first node. The first capacitor has a first end connected to the first node, and a second end connected to the ground. The second inductor has a first end connected to the second output terminal, and a second end connected to a second node. The second capacitor has a first end connected to the second node, and a second end connected to the ground. The third inductor has a first end connected to the first node, and a second end connected to a third node connected to a load. The third capacitor has a first end connected to the second node, and a second end connected to the third node.

A power amplifier circuit according to another aspect of the present disclosure includes a carrier amplifier, a peak amplifier, a first inductor, a first capacitor, a second inductor, a second capacitor, and a 90° hybrid coupler. The carrier amplifier amplifies a first signal, and outputs a first amplified signal from a first output terminal. The peak amplifier amplifies a second signal different in phase from the first signal, and outputs a second amplified signal from a second output terminal. The first inductor has a first end connected to the first output terminal, and a second end connected to a first node. The first capacitor has a first end connected to the first node, and a second end connected to the ground. The second inductor has a first end connected to the second output terminal, and a second end connected to a second node. The second capacitor has a first end connected to the second node, and a second end connected to the ground. The 90° hybrid coupler has a first input port, a second input port, an output port, and an isolation port. The first input port is connected to the first node and is supplied with the first amplified signal. The second input port is connected to the second node and is supplied with the second amplified signal. The output port is connected to a third node connected to a load and is a port from which an output signal is outputted.

A power amplifier circuit according to another aspect of the present disclosure includes a carrier amplifier, a peak amplifier, a first capacitor, a first inductor, a second capacitor, a second inductor, a third capacitor, and a third inductor. The carrier amplifier amplifies a first signal, and outputs a first amplified signal from a first output terminal. The peak amplifier amplifies a second signal different in phase from the first signal, and outputs a second amplified signal from a second output terminal. The first capacitor has a first end connected to the first output terminal, and a second end connected to a first node. The first inductor has a first end connected to the first node, and a second end connected to the ground. The second capacitor has a first end connected to the second output terminal, and a second end connected to a second node. The second inductor has a first end connected to the second node, and a second end connected to the ground. The third capacitor has a first end connected to the first node, and a second end connected to a third node connected to a load. The third inductor has a first end connected to the second node, and a second end connected to the third node.

A power amplifier circuit according to another aspect of the present disclosure includes a carrier amplifier, a peak amplifier, a first capacitor, a first inductor, a second capacitor, a second inductor, and a 90° hybrid coupler. The carrier amplifier amplifies a first signal, and outputs a first amplified signal from a first output terminal. The peak amplifier amplifies a second signal different in phase from the first signal, and outputs a second amplified signal from a second output terminal. The first capacitor has a first end connected to the first output terminal, and a second end connected to a first node. The first inductor has a first end connected to the first node, and a second end connected to the ground. The second capacitor has a first end connected to the second output terminal, and a second end connected to a second node. The second inductor has a first end connected to the second node, and a second end connected to the ground. The 90° hybrid coupler has a first input port, a second input port, an output port, and an isolation port. The first input port is connected to the first node and is supplied with the first amplified signal. The second input port is connected to the second node and is supplied with the second amplified signal. The output port is connected to a third node connected to a load and is a port from which an output signal is outputted.

A power amplifier circuit according to another aspect of the present disclosure includes a carrier amplifier, a peak amplifier, a first inductor, a first capacitor, a second inductor, a third capacitor, a fifth inductor, and a second capacitor. The carrier amplifier amplifies a first signal, and outputs a first amplified signal from a first output terminal. The peak amplifier amplifies a second signal different in phase from the first signal, and outputs a second amplified signal from a second output terminal.

The first inductor has a first end connected to the first output terminal, and a second end connected to a first node connected to a load. The first capacitor has a first end connected to the first node, and a second end connected to the ground. The second inductor has a first end connected to the second output terminal, and a second end connected to a second node. The third capacitor has a first end connected to the second node, and a second end connected to the first node. The fifth inductor and the second capacitor are connected in series between the second node and the ground.

### Effects of Disclosure

The present disclosure may provide a power amplifier circuit which achieves a reduction in size, high efficiency, and high resistance to fluctuations in load impedance.

### BRIEF DESCRIPTION OF THE DRAWINGS

FIG. 1 is a circuit diagram of a power amplifier circuit 101.

FIG. 2 is a circuit diagram of a power amplifier circuit 900 which is a reference example.

FIG. 3 is a diagram illustrating a simulation result of frequency characteristics of the change in phase across output terminals in the power amplifier circuit 900.

FIG. 4 is a diagram illustrating a simulation result of frequency characteristics of the change in phase across output terminals in the power amplifier circuit 101.

FIG. 5 is a diagram illustrating a simulation result of frequency characteristics of the phase difference between signals in the power amplifier circuit 900.

FIG. 6 is a diagram illustrating a simulation result of frequency characteristics of the phase difference between signals in the power amplifier circuit 101.

FIG. 7 is a circuit diagram of a power amplifier circuit 901 which is a reference example.

FIG. 8 is a diagram illustrating a simulation result of gain characteristics in the power amplifier circuit 101.

FIG. 9 is a diagram illustrating a simulation result of gain characteristics in the power amplifier circuit 900.

FIG. 10 is a diagram illustrating a simulation result of gain characteristics in the power amplifier circuit 901.

FIG. 11 is a diagram illustrating a simulation result of efficiency characteristics in the power amplifier circuit 101.

FIG. 12 is a diagram illustrating a simulation result of efficiency characteristics in the power amplifier circuit 900.

FIG. 13 is a diagram illustrating a simulation result of efficiency characteristics in the power amplifier circuit 901.

FIG. 14 is a diagram illustrating a Smith chart showing a simulation result of variations in impedance Zc relative to output power variations in the power amplifier circuit 101.

FIG. 15 is a diagram illustrating a Smith chart showing a simulation result of variations in impedance Zc relative to output power variations in the power amplifier circuit 900.

FIG. 16 is a diagram illustrating a Smith chart showing a simulation result of variations in impedance Zc relative to output power variations in the power amplifier circuit 901.

FIG. 17 is a diagram illustrating a Smith chart showing a simulation result of variations in impedance Zp relative to output power variations in the power amplifier circuit 101.

FIG. 18 is a diagram illustrating a Smith chart showing a simulation result of variations in impedance Zp relative to output power variations in the power amplifier circuit 900.

FIG. 19 is a diagram illustrating a Smith chart showing a simulation result of variations in impedance Zp relative to output power variations in the power amplifier circuit 901.

FIG. 20 is a diagram illustrating a Smith chart showing a simulation result of a change in impedance Zc relative to a change of load phase in the power amplifier circuit 101.

FIG. 21 is a diagram illustrating a Smith chart showing a simulation result of a change in impedance Zp relative to a change of load phase in the power amplifier circuit 101.

FIG. 22 is a diagram illustrating exemplary load fluctuation characteristics of power-added efficiency in the power amplifier circuit 101.

FIG. 23 is a circuit diagram of a power amplifier circuit 111.

FIG. 24 is a circuit diagram of a power amplifier circuit 102.

FIG. 25 is a diagram illustrating a simulation result of frequency characteristics of the change in phase across output terminals in the power amplifier circuit 102.

FIG. 26 is a diagram illustrating a simulation result of frequency characteristics of the phase difference between signals in the power amplifier circuit 102.

FIG. 27 is a circuit diagram of a power amplifier circuit 902 which is a reference example.

FIG. 28 is a diagram illustrating a simulation result of gain characteristics in the power amplifier circuit 102.

FIG. 29 is a diagram illustrating a simulation result of gain characteristics in the power amplifier circuit 902.

FIG. 30 is a diagram illustrating a simulation result of efficiency characteristics in the power amplifier circuit 102.

FIG. 31 is a diagram illustrating a simulation result of efficiency characteristics in the power amplifier circuit 902.

FIG. 32 is a diagram illustrating a Smith chart showing a simulation result of variations in impedance Zc relative to output power variations in the power amplifier circuit 102.

FIG. 33 is a diagram illustrating a Smith chart showing a simulation result of variations in impedance Zc relative to output power variations in the power amplifier circuit 902.

FIG. 34 is a diagram illustrating a Smith chart showing a simulation result of variations in impedance Zp relative to output power variations in the power amplifier circuit 102.

FIG. 35 is a diagram illustrating a Smith chart showing a simulation result of variations in impedance Zp relative to output power variations in the power amplifier circuit 902.

FIG. 36 is a circuit diagram of a power amplifier circuit 112.

FIG. 37 is a circuit diagram of a power amplifier circuit 122.

FIG. 38 is a circuit diagram of a power amplifier circuit 132.

FIG. 39 is a diagram illustrating exemplary load fluctuation characteristics of power-added efficiency in the power amplifier circuit 132.

FIG. 40 is a circuit diagram of a power amplifier circuit 141.

FIG. 41 is a diagram illustrating an exemplary capacitor 202v.

FIG. 42 is a diagram illustrating an exemplary capacitor 183v.

FIG. 43 is a diagram illustrating a Smith chart showing a simulation result of variations in impedance Zp relative to frequency variations in the power amplifier circuit 141.

FIG. 44 is a diagram illustrating a Smith chart showing a simulation result of variations in impedance Zc relative to frequency variations in the power amplifier circuit 141.

FIG. 45 is a diagram illustrating a Smith chart showing a simulation result of variations in impedance ZP2 relative to frequency variations in the power amplifier circuit 141.

FIG. 46 is a diagram illustrating a Smith chart showing a simulation result of variations in impedance ZP1 relative to frequency variations in the power amplifier circuit 141.

FIG. 47 is a diagram illustrating exemplary variations in loss relative to frequency variations in an LC circuit 181.

### DETAILED DESCRIPTION

Embodiments of the present disclosure will be described below in detail by referring to the drawings. The same components are designated with the same reference numerals, and repeated description will be avoided as much as possible.

### First Embodiment

A power amplifier circuit 101 according to a first embodiment will be described. FIG. 1 is a circuit diagram of the power amplifier circuit 101. As illustrated in FIG. 1, the power amplifier circuit 101 includes a carrier amplifier 51, a peak amplifier 52, LC circuits 61 and 62, and a 90° hybrid coupler 71.

The LC circuit 61 includes a capacitor 201 (first capacitor) and an inductor 211 (first inductor). The LC circuit 62 includes a capacitor 202 (second capacitor) and an inductor 212 (second inductor).

The 90° hybrid coupler 71 includes capacitors 203 (third capacitor) and 204 (fourth capacitor), and inductors 213 (third inductor) and 214 (fourth inductor).

The carrier amplifier 51 amplifies a signal RF1 (first signal) and outputs an amplified signal RF3 (first amplified signal) from an output terminal 51a (first output terminal).

The peak amplifier 52 amplifies a signal RF2 (second signal), which is different in phase from the signal RF1, and outputs an amplified signal RF4 (second amplified signal) from an output terminal 52a.

In detail, the signals RF1 and RF2 are, for example, radio frequency (RF) signals. The signals RF1 and RF2 are signals generated by a splitter (not illustrated) splitting an input signal. The phases of the signals RF1 and RF2 just after being outputted from the splitter are, for example, identical.

The signal RF2 is supplied to the peak amplifier 52 through a quarter-wave line (not illustrated), whereas the signal RF1 is supplied to the carrier amplifier 51 as it is. Therefore, the phase of the signal RF2 supplied to the peak amplifier 52 is delayed by approximately 90° compared with the phase of the signal RF1 supplied to the carrier amplifier 51.

The output terminal 51a of the carrier amplifier 51 is grounded through a capacitor 301. The output terminal 52a of the peak amplifier 52 is grounded through a capacitor 302. The capacitors 301 and 302 are, for example, parasitic capacities, or are capacities provided for harmonic-wave control.

The LC circuit 61 is connected between the output terminal 51a of the carrier amplifier 51 and an input port Pin1 in the 90° hybrid coupler 71. In detail, the inductor 211 (first inductor) in the LC circuit 61 has a first end connected to the output terminal 51a, and a second end connected to a node N1 (first node). The capacitor 201 has a first end connected to the node N1 and a second end connected to the ground.

The LC circuit 62 is connected between the output terminal 52a of the peak amplifier 52 and an input port Pin2 in the 90° hybrid coupler 71. In detail, the inductor 212 in the LC circuit 62 has a first end connected to the output terminal 52a, and a second end connected to a node N2 (second node). The capacitor 202 has a first end connected to the node N2, and a second end connected to the ground.

The inductor 213 in the 90° hybrid coupler 71 has a first end, which is connected to the node N1 and which is the input port Pin1 (first input port) supplied with the amplified signal RF3, and a second end, which is connected to a node N3 (third node) and which is an output port Pout. The node N3 is grounded through a load 86. An output signal RFout, which is obtained by combining the amplified signals RF3 and RF4 with each other, is outputted from the output port Pout through the node N3 to the load 86.

The capacitor 203 has a first end, which is connected to the node N2 and which is the input port Pin2 (second input port) supplied with the amplified signal RF4, and a second end connected to the node N3.

The capacitor 204 has a first end connected to the node N1, and a second end which is an isolation port Piso. The isolation port Piso is not connected to circuit elements external to the 90° hybrid coupler 71. That is, the isolation port Piso is not connected directly to all the circuit elements, except the capacitor 204 and the inductor 214 which are included in the 90° hybrid coupler 71.

The inductor 214 has a first end connected to the node N2, and a second end connected to the second end of the capacitor 204, and is electromagnetically coupled to the inductor 213.

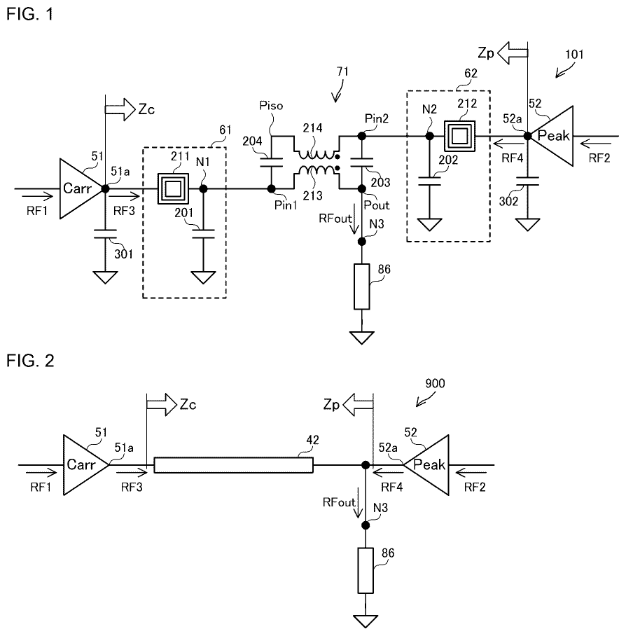

FIG. 2 is a circuit diagram of a power amplifier circuit 900 which is a reference example. As illustrated in FIG. 2, the power amplifier circuit 900 is a Doherty amplifier circuit of the related art. Compared with the power amplifier circuit 101 in FIG. 1, the power amplifier circuit 900 includes a quarter-wave line 42 instead of the LC circuits 61 and 62, the 90° hybrid coupler 71, and the capacitors 301 and 302.

The quarter-wave line 42 has a first end connected to the output terminal 51a of the carrier amplifier 51, and a second end connected to the output terminal 52a of the peak amplifier 52. The node N3 is connected to the output terminal 52a.

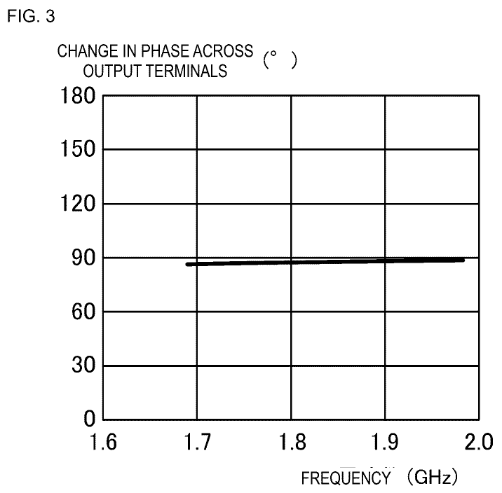

FIG. 3 is a diagram illustrating a simulation result of the frequency characteristics of the change in phase across the output terminals in the power amplifier circuit 900. The vertical axis indicates the change in phase, whose unit is “°”, across the output terminals. The horizontal axis indicates the frequency of the amplified signals RF3 and RF4. The change in phase across the output terminals is a change in phase of the amplified signal RF3 which is obtained when the amplified signal RF3 has passed from the output terminal 51a of the carrier amplifier 51 through the quarter-wave line 42 to the output terminal 52a of the peak amplifier 52.

As illustrated in FIG. 3, in the power amplifier circuit 900, the change in phase across the output terminals of the amplified signal RF3 is approximately 90° in the range from 1.68 GHz to 1.98 GHz.

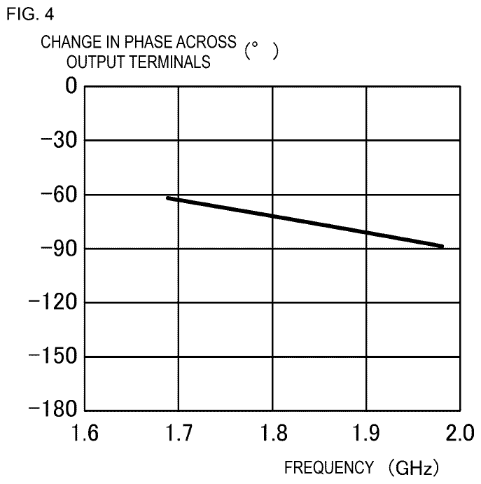

FIG. 4 is a diagram illustrating a simulation result of the frequency characteristics of the change in phase across the output terminals in the power amplifier circuit 101. The vertical axis indicates the change in phase, whose unit is “°”, across the output terminals. The horizontal axis indicates the frequency of the amplified signals RF3 and RF4. The change in phase across the output terminals in this case is a change in phase of the amplified signal RF3 which is obtained when the amplified signal RF3 has passed from the output terminal 51a of the carrier amplifier 51 through the nodes N1 and N2 to the output terminal 52a of the peak amplifier 52.

In the power amplifier circuit 101, the magnitude of the change in phase across the output terminals of the amplified signal RF3 is greater than or equal to 45° and less than or equal to 135°. In the present embodiment, as illustrated in FIG. 4, the magnitude of the change in phase across the output terminals of the amplified signal RF3 is greater than or equal to 60° and less than or equal to 90° in the range from 1.68 GHz to 1.98 GHz. That is, the change in phase across the output terminals, which is comparable to that in the power amplifier circuit 900, is achieved.

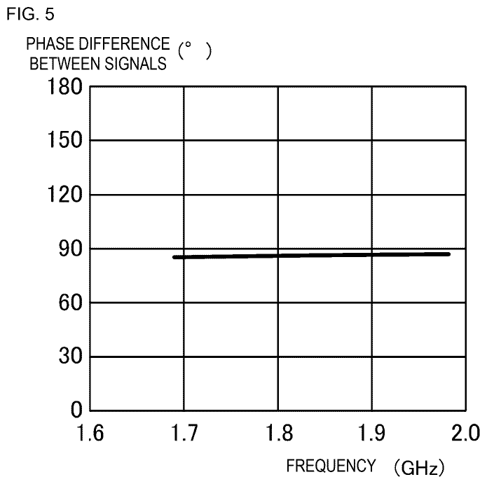

FIG. 5 is a diagram illustrating a simulation result of the frequency characteristics of the phase difference between signals in the power amplifier circuit 900. The vertical axis indicates the phase difference, whose unit is “°”, between signals. The horizontal axis indicates the frequency of the amplified signals RF3 and RF4. The phase difference between signals indicates the difference between the change in phase, which is obtained when the amplified signal RF3 outputted from the output terminal 51a of the carrier amplifier 51 passes through the quarter-wave line 42 and the load 86, and the change in phase, which is obtained when the amplified signal RF4 outputted from the output terminal 52a of the peak amplifier 52 passes through the load 86.

As illustrated in FIG. 5, in the power amplifier circuit 900, the phase difference between the signals is approximately 90° in the range from 1.68 GHz to 1.98 GHz.

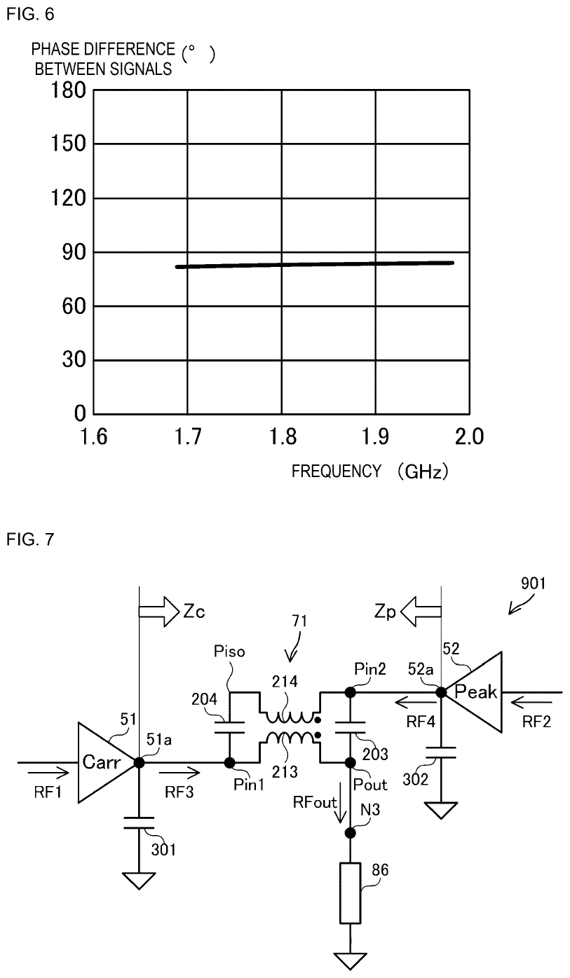

FIG. 6 is a diagram illustrating a simulation result of the frequency characteristics of the phase difference between the signals in the power amplifier circuit 101. The vertical axis indicates the phase difference, whose unit is “°”, between the signals. The horizontal axis indicates the frequency, whose unit is “GHz”, of the amplified signals RF3 and RF4. The phase difference between the signals in this case indicates the difference between the change in phase, which is obtained when the amplified signal RF3 outputted from the output terminal 51a of the carrier amplifier 51 passes through the nodes N1 and N3 and the load 86, and the change in phase, which is obtained when the amplified signal RF4 outputted from the output terminal 52a of the peak amplifier 52 passes through the nodes N2 and N3 and the load 86.

In the power amplifier circuit 101, the magnitude of the phase difference between the signals is greater than or equal to 60° and less than or equal to 120°. In the present embodiment, as illustrated in FIG. 6, the magnitude of the phase difference between the signals is approximately 90° in the range from 1.68 GHz to 1.98 GHz. That is, the phase difference between the signals, which is comparable to that in the power amplifier circuit 900, is achieved.

FIG. 7 is a circuit diagram of a power amplifier circuit 901 which is a reference example. As illustrated in FIG. 7, compared with the power amplifier circuit 101 in FIG. 1, the power amplifier circuit 901 is a circuit in which the LC circuits 61 and 62 are not disposed.

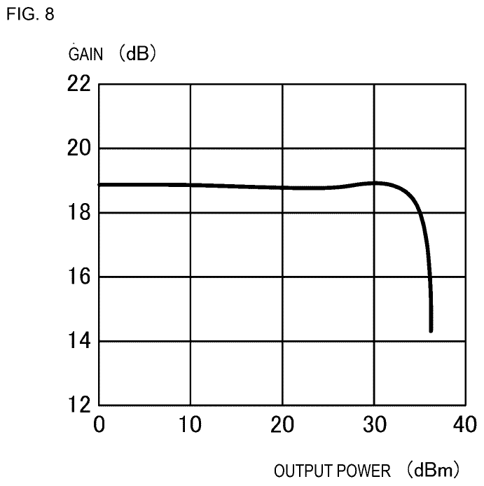

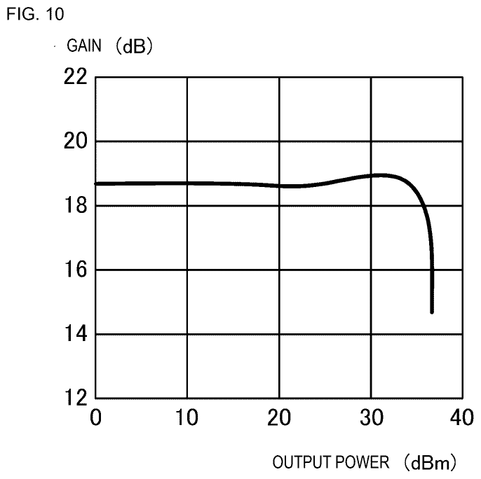

FIGS. 8, 9, and 10 are diagrams illustrating simulation results of gain characteristics in the power amplifier circuits 101, 900, and 901, respectively. The vertical axis indicates gain, whose unit is “dB”, of a power amplifier circuit. The horizontal axis indicates power, whose unit is “dBm”, of the output signal RFout (hereinafter may be referred to as output power).

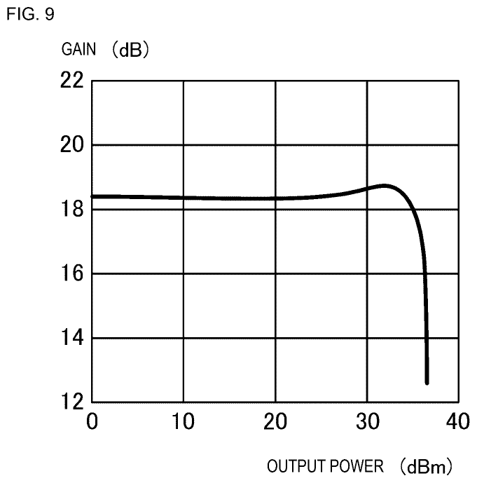

The gain characteristics in FIGS. 8 to 10 are obtained when idle current to the peak amplifier 52 is throttled (hereinafter may referred to as “in Doherty operation”). The frequency of the signals RF1 and RF2 is 1.8 GHz. The gain characteristics (see FIG. 8) in the power amplifier circuit 101 are comparable to the gain characteristics (see FIG. 9) in the power amplifier circuit 900.

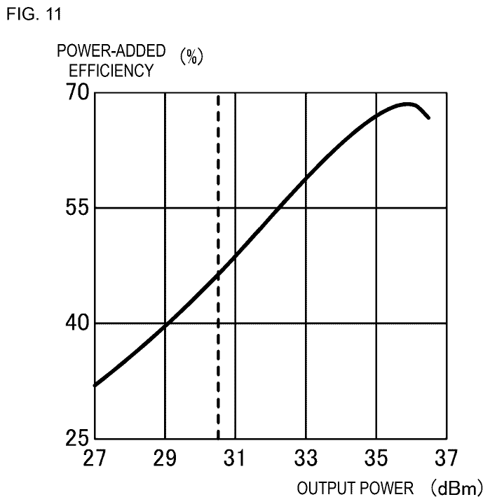

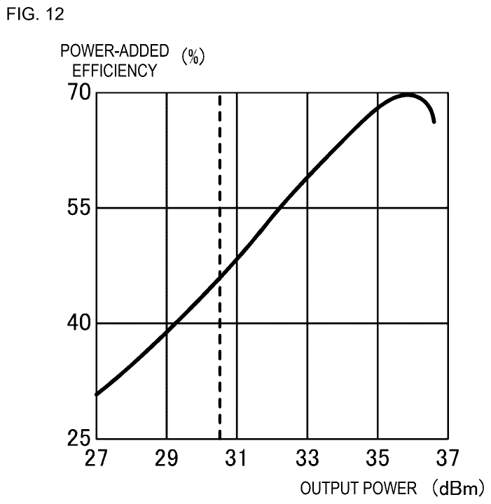

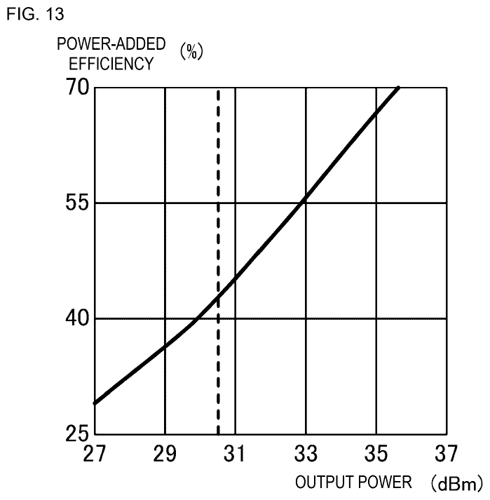

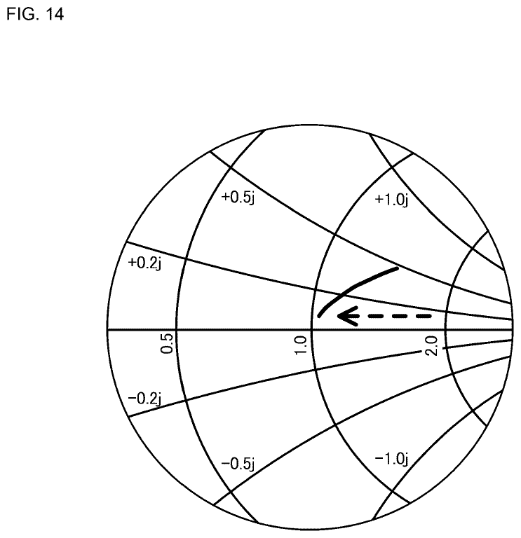

FIGS. 11, 12, and 13 are diagrams illustrating simulation results of efficiency characteristics in the power amplifier circuits 101, 900, and 901, respectively. The vertical axis indicates the power-added efficiency, whose unit is “%”, of a power amplifier circuit. The horizontal axis indicates output power whose unit is “dBm”.

The efficiency characteristics in FIGS. 11 to 13 are obtained in Doherty operation. The frequency of the signals RF1 and RF2 is 1.8 GHz. The output power indicated by using a dotted line is power which is actually used (hereinafter may be referred to as actual power in use) in the power amplifier circuits 101, 900, and 901.

The power-added efficiency of the power amplifier circuit 101 at the actual power in use is greater than that of the power amplifier circuit 901 at the actual power in use. The power-added efficiency of the power amplifier circuit 101 at the actual power in use is comparable to that of the power amplifier circuit 900 at the actual power in use.

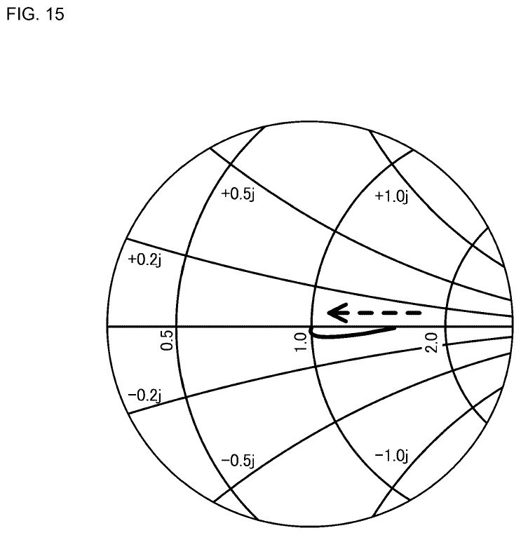

FIGS. 14, 15, and 16 are diagrams illustrating Smith charts showing simulation results of variations in impedance Zc relative to output power variations in the power amplifier circuits 101, 900, and 901, respectively. Impedance Zc is impedance as seen from the output terminal 51a of the carrier amplifier 51 to the load 86.

The variations in impedance Zc relative to output power variations, which are illustrated in FIGS. 14 to 16, are obtained in Doherty operation. The frequency of the signals RF1 and RF2 is 1.8 GHz. When the real number component of impedance Zc is large, the power-added efficiency increases. The direction of the arrow indicated by using a dotted line indicates increase of output power.

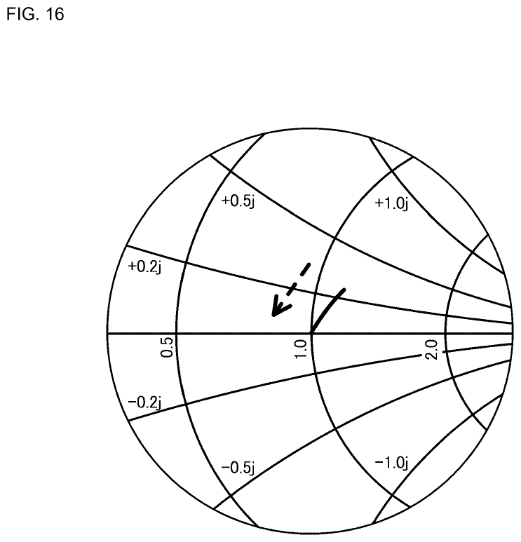

In the power amplifier circuit 901 having only the 90° hybrid coupler 71, impedance Zc varies along the imaginary number axis (see FIG. 16). In contrast, in the power amplifier circuit 900, impedance Zc varies along the real number axis, showing that power-added efficiency is high (see FIG. 15).

In the power amplifier circuit 101 in which low-pass filter circuits of the LC circuits 61 and 62 are disposed, variations in impedance Zc relative to output power variations may be made close to that in the power amplifier circuit 900 (see FIGS. 14 and 15).

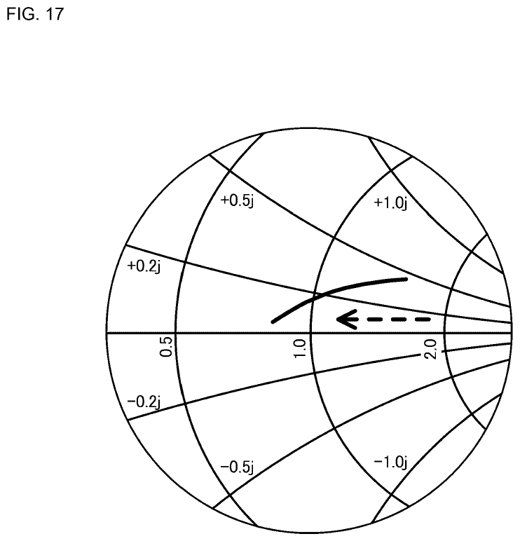

FIGS. 17, 18, and 19 are diagrams illustrating Smith charts showing simulation results of variations in impedance Zp relative to output power variations in the power amplifier circuits 101, 900, and 901, respectively. Impedance Zp is impedance as seen from the output terminal 52a of the peak amplifier 52 to the load 86.

The variations in impedance Zp relative to output power variations in FIGS. 17 to 19 are obtained in Doherty operation. The frequency of the signals RF1 and RF2 is 1.8 GHz. When the real number component of impedance Zp is large, the power-added efficiency increases. The direction of the arrow indicated by using a dotted line indicates increase of output power.

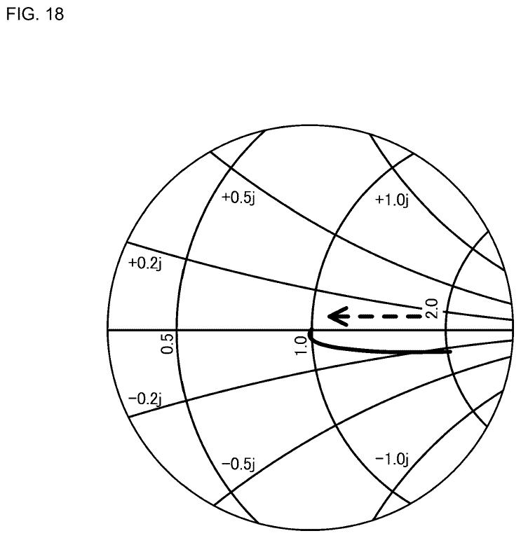

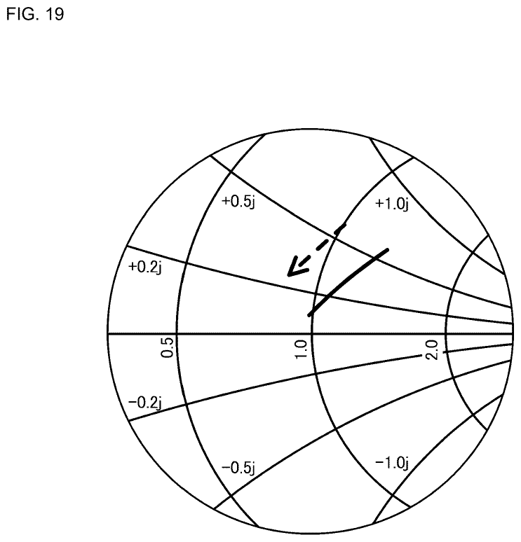

In the power amplifier circuit 901 having only the 90° hybrid coupler 71, impedance Zp varies along the imaginary number axis (see FIG. 19). In contrast, in the power amplifier circuit 900, impedance Zp varies along the real number axis, showing that power-added efficiency is high (see FIG. 18).

In the power amplifier circuit 101 in which the low-pass filter circuits of the LC circuits 61 and 62 are disposed, variations in impedance Zp relative to output power variations may be made close to that in the power amplifier circuit 900 (see FIGS. 17 and 18).

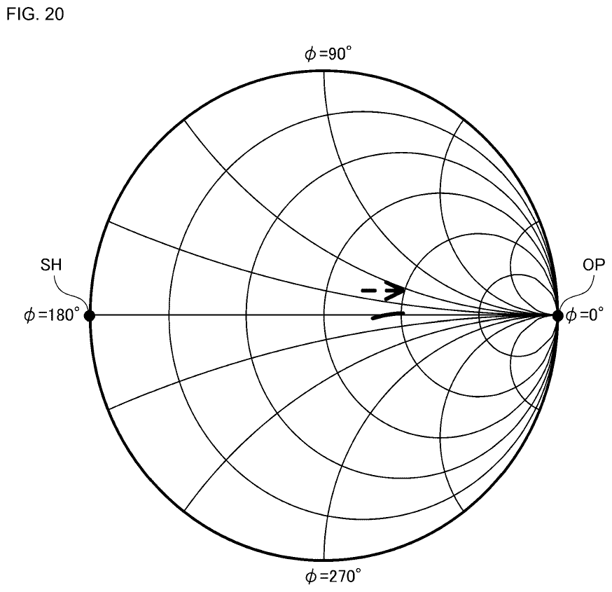

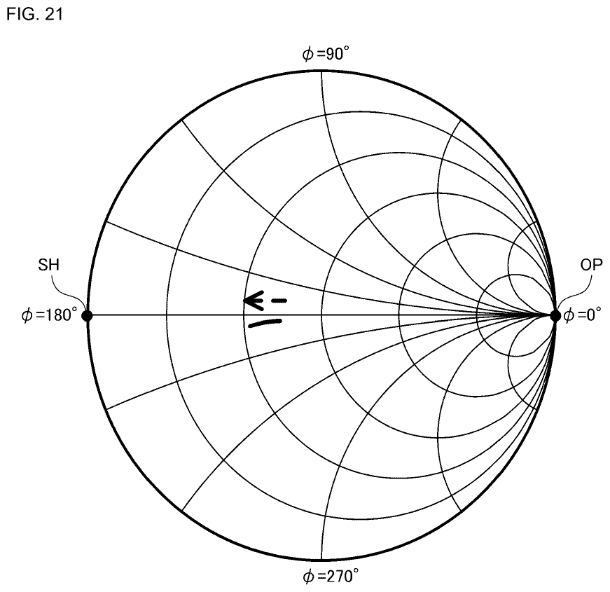

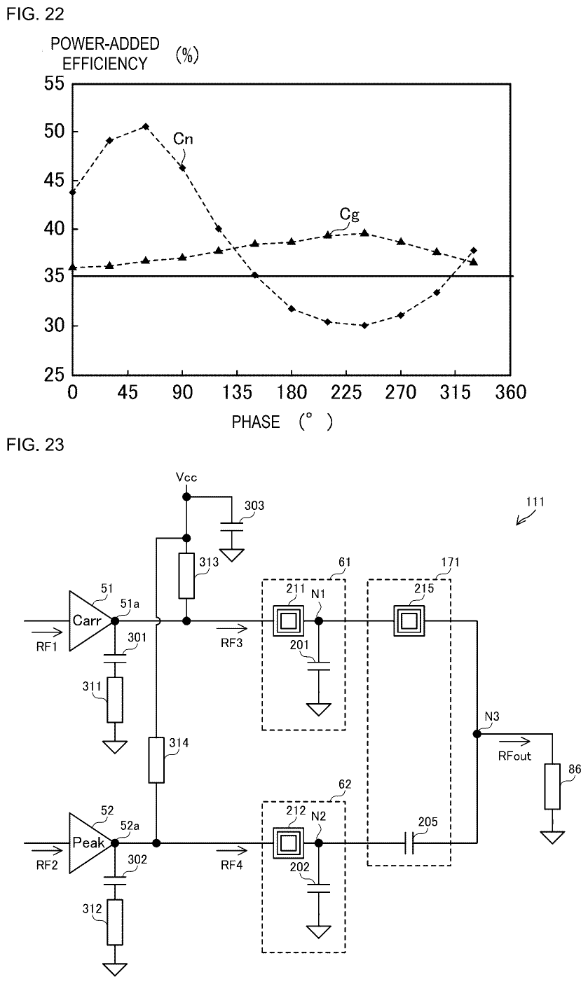

FIGS. 20 and 21 are diagrams illustrating Smith charts showing simulation results of a change in impedance Zc and a change in impedance Zp, respectively, relative to a change of load phase in the power amplifier circuit 101. FIG. 22 is a diagram illustrating exemplary load fluctuation characteristics of the power-added efficiency in the power amplifier circuit 101. The vertical axis indicates the power-added efficiency, whose unit is “%”, of the power amplifier circuit. The horizontal axis indicates the phase of an antenna 86a end, whose unit is “°” and which is obtained when VSWR (Voltage Standing Wave Ratio) is two.

As illustrated in FIGS. 20 to 22, in the power amplifier circuit 101, the signals RF1 and RF2, which have a phase difference of approximately 90°, are amplified by the carrier amplifier 51 and the peak amplifier 52, respectively. When the phase of the load 86 fluctuates, as illustrated in FIG. 20, the output impedance Zc of the carrier amplifier 51 is shifted to the open OP side. At that time, as illustrated in FIG. 21, the output impedance Zp of the peak amplifier 52 is easily shifted to the short SH side by the same shift amount.

Thus, as illustrated in FIG. 22, compared with the fluctuation, which is illustrated by using curve Cn, of the power-added efficiency of an amplifier circuit including an amplifier of the related art such as a differential amplifier or a two-stage amplifier, the fluctuation, which is illustrated by using curve Cg, of the power-added efficiency of the power amplifier circuit 101 may be suppressed. That is, the resistance to load fluctuation in the power amplifier circuit 101 may be improved compared with that in an amplifier circuit of the related art.

In the present embodiment, the configuration, in which the 90° hybrid coupler 71 is formed by using the capacitors 203 and 204 and the inductors 213 and 214, is described. However, the configuration is not limited to this. The 90° hybrid coupler 71 may have a configuration in which four quarter-wave lines are connected in a circle.

### Second Embodiment

A power amplifier circuit 111 according to a second embodiment will be described. Points common to those in the first embodiment will not be described in the second embodiment and its subsequent embodiments, and only different points will be described. In particular, substantially the same operational effect caused by substantially the same configuration will not be described repeatedly.

FIG. 23 is a circuit diagram of a power amplifier circuit 111. As illustrated in FIG. 23, the power amplifier circuit 111 is different from the power amplifier circuit 101 according to the first embodiment in that an LC circuit 171 is disposed instead of the 90° hybrid coupler 71.

The LC circuit 171 includes a capacitor 205 (third capacitor) and an inductor 215 (third inductor). The inductor 215 has a first end connected to the node N1, and a second end connected to the node N3. The capacitor 205 has a first end connected to the node N2, and a second end connected to the node N3.

A capacitor 303 has a first end connected to a power supply voltage VCC, and a second end connected to the ground. A line 313 has a first end connected to the power supply voltage VCC, and a second end connected to the output terminal 51a of the carrier amplifier 51. A line 314 has a first end connected to the power supply voltage VCC, and a second end connected to the output terminal 52a of the peak amplifier 52. The capacitor 303 and the lines 313 and 314 may be disposed in the power amplifier circuit 101.

The output terminal 51a of the carrier amplifier 51 is grounded through the capacitor 301 and a line 311. The output terminal 52a of the peak amplifier 52 is grounded through the capacitor 302 and a line 312.

Thus, even the configuration, in which the LC circuit 171 which is simpler than the 90° hybrid coupler 71 is disposed, may achieve characteristics equivalent to those of the power amplifier circuit 101. In other words, the power amplifier circuit 111 may also achieve power-added efficiency equivalent to that of the power amplifier circuit 101 in FIG. 1.

### Third Embodiment

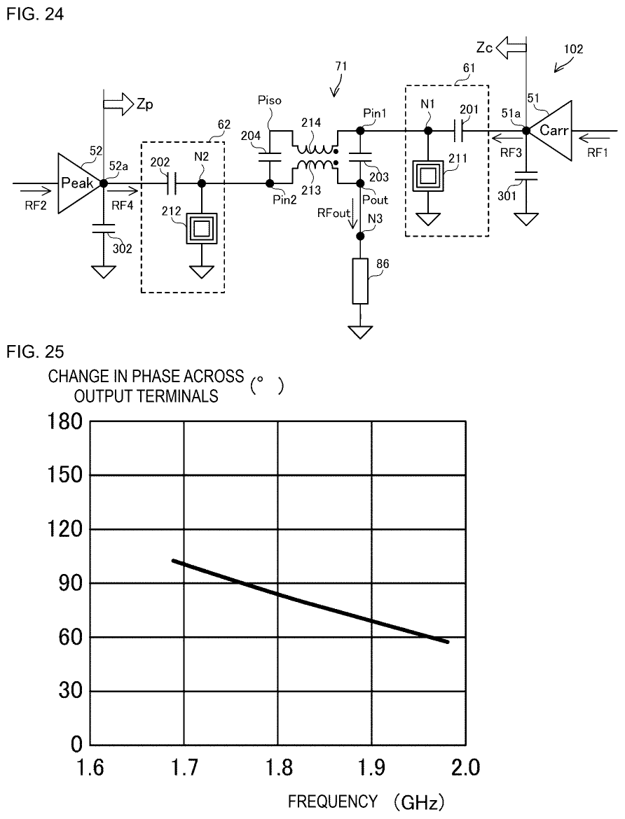

A power amplifier circuit 102 according to a third embodiment will be described. FIG. 24 is a circuit diagram of a power amplifier circuit 102. As illustrated in FIG. 24, the power amplifier circuit 102 according to the third embodiment is different from the power amplifier circuit 101 in FIG. 1 according to the first embodiment in the connection form of the elements.

The capacitor 201 in the LC circuit 61 has its first end connected to the output terminal 51a, and its second end connected to the node N1. The inductor 211 has its first end connected to the node N1, and its second end connected to the ground.

The capacitor 202 in the LC circuit 62 has its first end connected to the output terminal 52a, and its second end connected to the node N2. The inductor 212 has its first end connected to the node N2, and its second end connected to the ground.

The inductor 213 in the 90° hybrid coupler 71 has its first end, which is connected to the node N2 and which is the input port Pin2 supplied with the amplified signal RF4, and its second end, which is connected to the node N3 and which is the output port Pout.

The capacitor 203 has its first end, which is connected to the node N1 and which is the input port Pin1 supplied with the amplified signal RF3, and its second end connected to the node N3.

The capacitor 204 has its first end connected to the node N2, and its second end which is the isolation port Piso. The isolation port Piso is not connected to circuit elements external to the 90° hybrid coupler 71.

The inductor 214 has its first end connected to the node N1, and its second end connected to the second end of the capacitor 204, and is electromagnetically coupled to the inductor 213.

FIG. 25 is a diagram illustrating a simulation result of the frequency characteristics of the change in phase across the output terminals in the power amplifier circuit 102. The vertical axis indicates the change in phase, whose unit is “°”, across the output terminals. The horizontal axis indicates the frequency of the amplified signals RF3 and RF4. The change in phase across the output terminals in this case is substantially the same as that in FIG. 4.

In the power amplifier circuit 102, the magnitude of the change in phase across the output terminals of the amplified signal RF3 is greater than or equal to 45° and less than or equal to 135°. In the present embodiment, as illustrated in FIG. 25, the magnitude of the change in phase across the output terminals of the amplified signal RF3 is greater than or equal to 50° and less than or equal to 115° in the range from 1.68 GHz to 1.98 GHz. That is, the change in phase across the output terminals comparable to that in the power amplifier circuit 900 (see FIG. 3) is achieved.

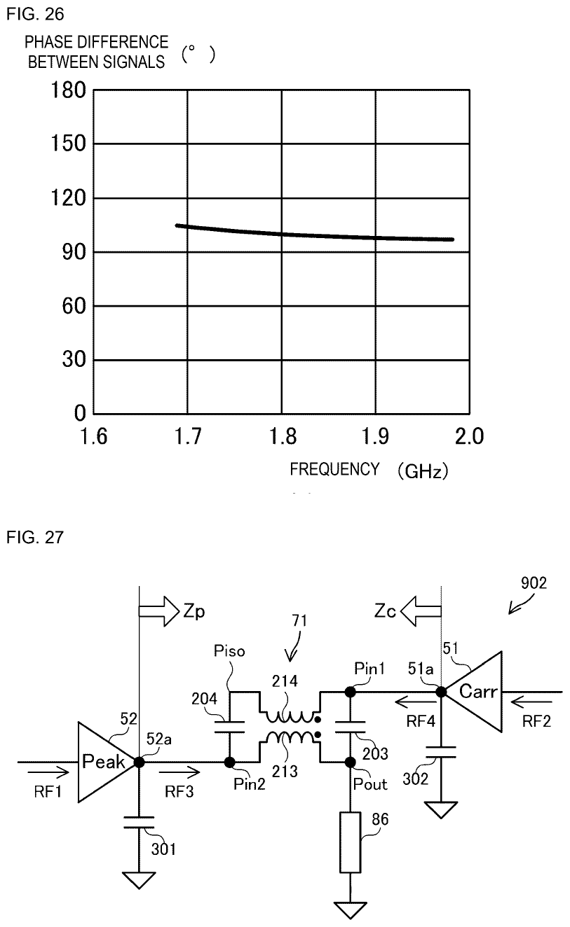

FIG. 26 is a diagram illustrating a simulation result of the frequency characteristics of the phase difference between the signals in the power amplifier circuit 102. The vertical axis indicates the phase difference, whose unit is “°”, between the signals. The horizontal axis indicates the frequency of the amplified signals RF3 and RF4. The phase difference between the signals in this case is substantially the same as that in FIG. 6.

In the power amplifier circuit 101, the magnitude of the phase difference between the signals is greater than or equal to 60° and less than or equal to 120°. In the present embodiment, as illustrated in FIG. 26, the magnitude of the phase difference between the signals is greater than or equal to 90° and less than or equal to 115° in the range from 1.68 GHz to 1.98 GHz. That is, the phase difference between the signals comparable to that in the power amplifier circuit 900 (see FIG. 5) is achieved.

FIG. 27 is a circuit diagram of a power amplifier circuit 902 which is a reference example. As illustrated in FIG. 27, compared with the power amplifier circuit 102 in FIG. 24, the power amplifier circuit 902 is a circuit in which the LC circuits 61 and 62 are not disposed.

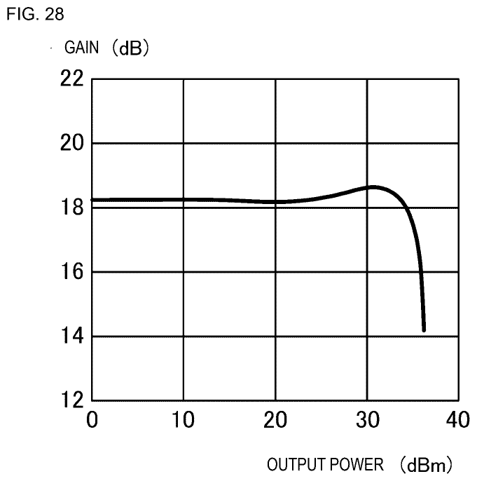

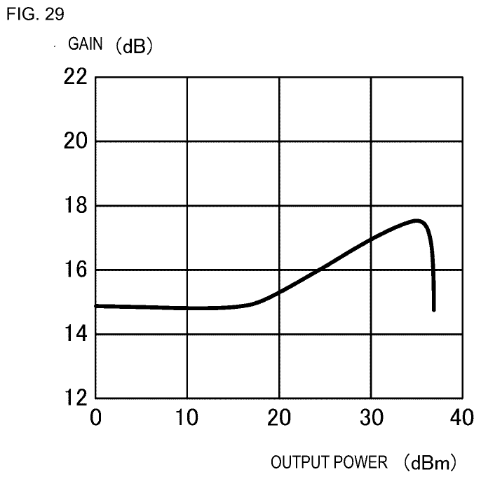

FIGS. 28 and 29 are diagrams illustrating simulation results of the gain characteristics of the power amplifier circuits 102 and 902, respectively. Reading of FIGS. 28 and 29 is substantially the same as that of FIGS. 8 to 10.

The gain characteristics in FIGS. 28 and 29 are obtained in Doherty operation. The frequency of the signals RF1 and RF2 is 1.8 GHz. The gain characteristics in the power amplifier circuit 102 (see FIG. 28) are higher than that in the power amplifier circuit 902 (see FIG. 29), and are comparable to that in the power amplifier circuit 900 (see FIG. 9).

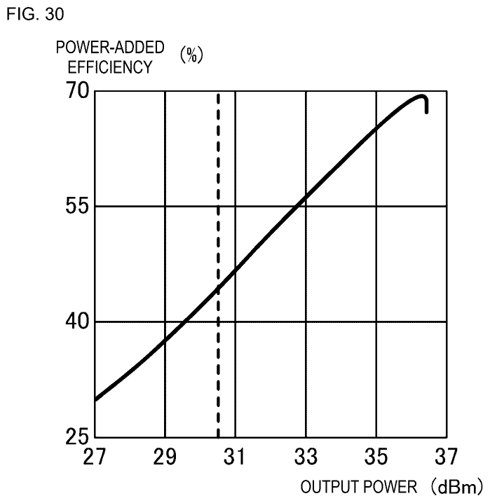

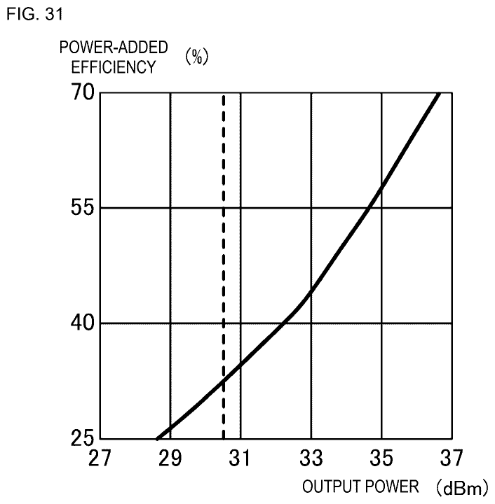

FIGS. 30 and 31 are diagrams illustrating simulation results of efficiency characteristics in the power amplifier circuits 102 and 902, respectively. Reading of FIGS. 30 and 31 is substantially the same as that of FIGS. 11 to 13.

The efficiency characteristics in FIGS. 30 and 31 are obtained in Doherty operation. The frequency of the signals RF1 and RF2 is 1.8 GHz. The output power indicated by using a dotted line is the actual power in use.

The power-added efficiency of the power amplifier circuit 102 at the actual power in use is greater than that of the power amplifier circuit 902 at the actual power in use. The power-added efficiency of the power amplifier circuit 102 at the actual power in use is comparable to that of the power amplifier circuit 900 at the actual power in use.

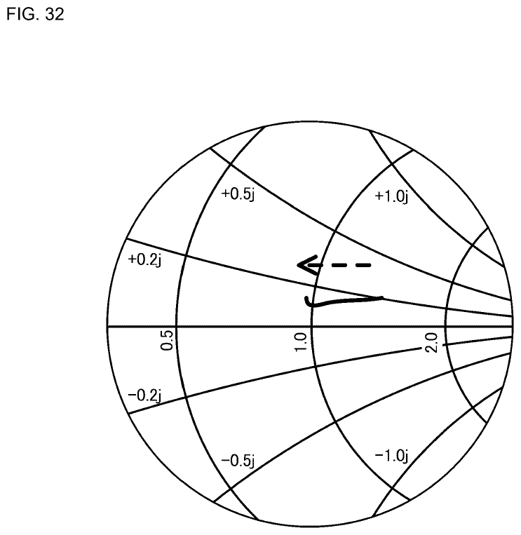

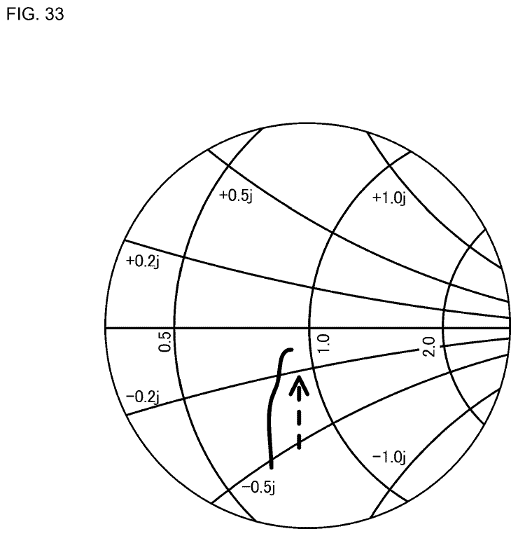

FIGS. 32 and 33 are diagrams illustrating Smith charts showing simulation results of variations in impedance Zc relative to output power variations in the power amplifier circuits 102 and 902, respectively.

The variations in impedance Zc relative to output power variations, which are illustrated in FIGS. 32 and 33, are obtained in Doherty operation. The frequency of the signals RF1 and RF2 is 1.8 GHz. The direction of an arrow indicated by using a dotted line indicates increase of output power.

In the power amplifier circuit 902 having only the 90° hybrid coupler 71, impedance Zc varies along the imaginary number axis (see FIG. 33).

In the power amplifier circuit 102 in which high-pass filter circuits of the LC circuits 61 and 62 are disposed, variations in impedance Zc relative to output power variations may be made close to those in the power amplifier circuit 900 (see FIGS. 15 and 32).

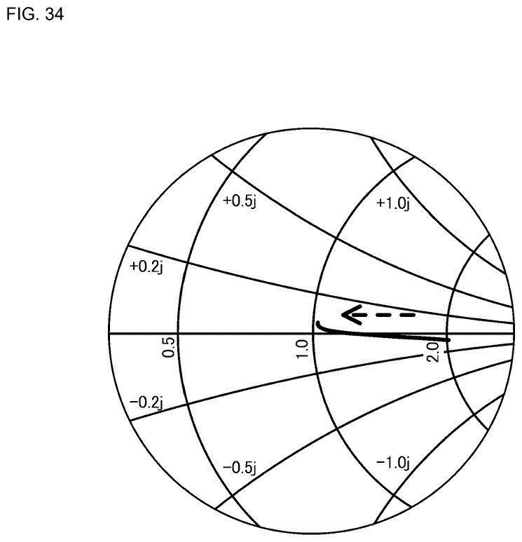

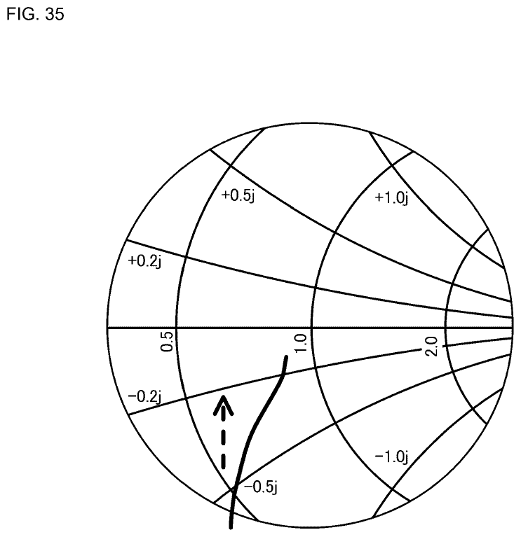

FIGS. 34 and 35 are diagrams illustrating Smith charts showing simulation results of variations in impedance Zp relative to output power variations in the power amplifier circuits 102 and 902, respectively.

The variations in impedance Zp relative to output power variations, which are illustrated in FIGS. 34 and 35, are obtained in Doherty operation. The frequency of the signals RF1 and RF2 is 1.8 GHz. The direction of an arrow indicated by using a dotted line indicates increase of output power.

In the power amplifier circuit 902 having only the 90° hybrid coupler 71, impedance Zp varies along the imaginary number axis (see FIG. 35).

In the power amplifier circuit 102 in which the high-pass filter circuits of the LC circuits 61 and 62 are disposed, variations in impedance Zp relative to output power variations may be made close to that in the power amplifier circuit 900 (see FIGS. 18 and 34).

In the present embodiment, the configuration, in which the 90° hybrid coupler 71 is formed by using the capacitors 203 and 204 and the inductors 213 and 214, is described. However, the configuration is not limited to this. The 90° hybrid coupler 71 may have a configuration in which four quarter-wave lines are connected in a circle.

### Fourth Embodiment

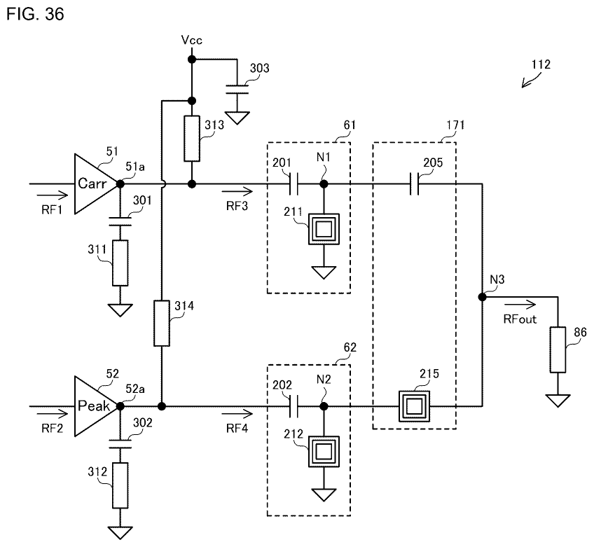

A power amplifier circuit 112 according to a fourth embodiment will be described. FIG. 36 is a circuit diagram of the power amplifier circuit 112. As illustrated in FIG. 36, the power amplifier circuit 112 is different from the power amplifier circuit 102 according to the third embodiment in that the LC circuit 171 is disposed instead of the 90° hybrid coupler 71.

The LC circuit 171 includes the capacitor 205 (third capacitor) and the inductor 215 (third inductor). The capacitor 205 has its first end connected to the node N1, and its second end connected to the node N3. The inductor 215 has its first end connected to the node N2, and its second end connected to the node N3.

The capacitor 303 and the lines 311 to 314 are substantially the same as the capacitor 303 and the lines 311 to 314, respectively, in the power amplifier circuit 111 in FIG. 23.

Thus, the configuration, having the LC circuit 171 which is simpler than the 90° hybrid coupler 71, also achieves characteristics equivalent to those of the power amplifier circuit 102.

### Fifth Embodiment

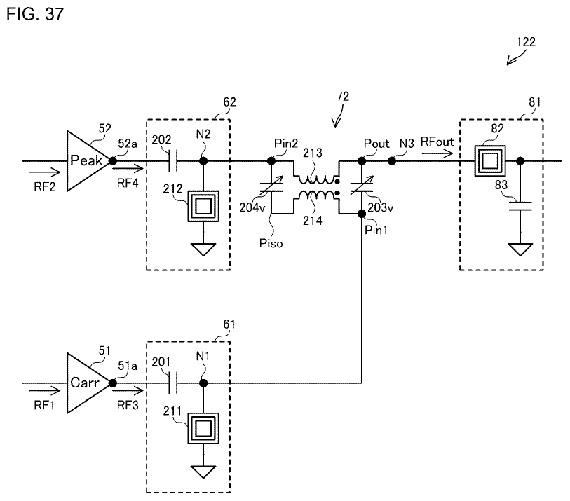

A power amplifier circuit 122 according to a fifth embodiment will be described. FIG. 37 is a circuit diagram of the power amplifier circuit 122. As illustrated in FIG. 37, the power amplifier circuit 122 is different from the power amplifier circuit 102 according to the third embodiment in that the capacities of the capacitors in the 90° hybrid coupler 71 are variable.

Compared with the power amplifier circuit 102 in FIG. 24, the power amplifier circuit 122 includes a 90° hybrid coupler 72 and an LC circuit 81 instead of the 90° hybrid coupler 71 and the capacitors 301 and 302.

Compared with the 90° hybrid coupler 71 in FIG. 24, the 90° hybrid coupler 72 includes capacitors 203v (third capacitor) and 204v (fourth capacitor) instead of the capacitors 203 and 204, respectively. The capacity of the capacitor 203v and that of the capacitor 204v are variable.

The LC circuit 81 includes an inductor 82 and a capacitor 83, and is disposed between the node N3 and the load 86 (not illustrated). The inductor 82 has a first end connected to the output port Pout of the 90° hybrid coupler 72, and a second end connected to the load 86. The capacitor 83 has a first end connected to the second end of the inductor 82, and a second end connected to the ground.

Adjustment of the capacity of the capacitor 203v and that of the capacitor 204v enables the frequency characteristics of the change in phase across the output terminals in the power amplifier circuit 122 to be changed. Specifically, the frequency characteristics of the change in phase across the output terminals in FIG. 25 may be shifted in the vertical-axis direction.

The capacity of the capacitor 203v and that of the capacitor 204v are adjusted appropriately in accordance with the frequency band of the signals RF1 and RF2. Thus, optimal change in phase across the output terminals is achieved in the frequency band. This enables the power amplifier circuit 122 to operate in a wide band excellently. In the present embodiment, the configuration of the power amplifier circuit 122, in which the capacities of the capacitors 203 and 204 of the 90° hybrid coupler 71 in the power amplifier circuit 102 are made variable, is described. However, the configuration is not limited to this. The capacities of the capacitors 203 and 204 of the 90° hybrid coupler 71 in the power amplifier circuit 101 may be made variable.

### Sixth Embodiment

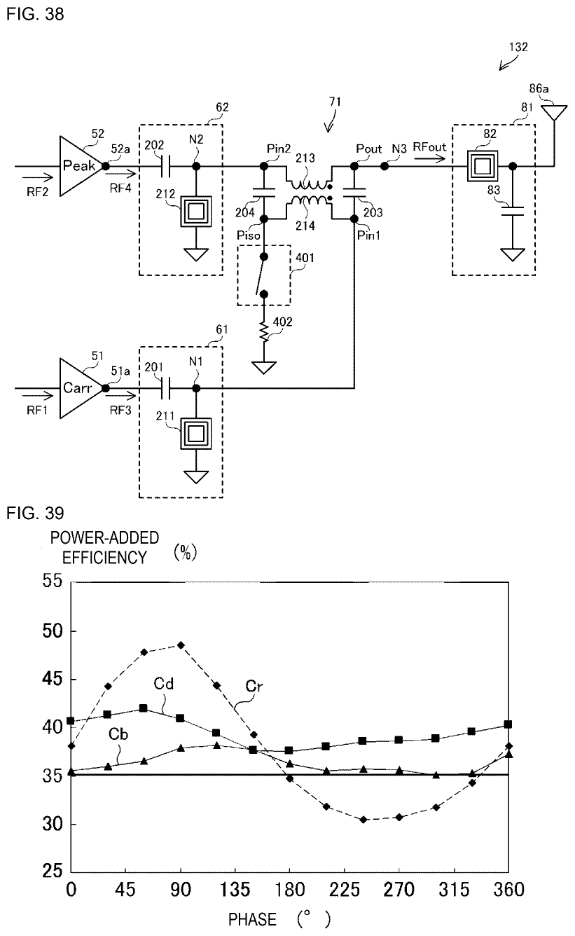

A power amplifier circuit 132 according to a sixth embodiment will be described. FIG. 38 is a circuit diagram of the power amplifier circuit 132. As illustrated in FIG. 38, the power amplifier circuit 132 is different from the power amplifier circuit 102 according to the third embodiment in that the isolation port Piso in the 90° hybrid coupler 71 may be grounded through a resistive element.

Compared with the power amplifier circuit 102 in FIG. 24, the power amplifier circuit 132 includes the LC circuit 81, a switch 401, and a resistive element 402 instead of the capacitors 301 and 302.

In the power amplifier circuit 132, the resistive element 402 and the switch 401 are connected in series between the isolation port Piso of the 90° hybrid coupler 71 and the ground.

In the present embodiment, the switch 401 has a first end connected to the isolation port Piso of the 90° hybrid coupler 71, and a second end connected to the ground through the resistive element 402. The switch 401 may be connected, at its first end, to the isolation port Piso through the resistive element 402, and may be connected, at its second end, to the ground.

The LC circuit 81 includes the inductor 82 and the capacitor 83, and is disposed between the node N3 and the antenna 86a (load). The inductor 82 has its first end connected to the output port Pout of the 90° hybrid coupler 71, and its second end connected to the antenna 86a. The capacitor 83 has its first end connected to the second end of the inductor 82, and its second end connected to the ground.

When the switch 401 is ON and the isolation port Piso is grounded through the resistive element 402, the power amplifier circuit 132 operates in a first mode (hereinafter may be referred to as balance mode).

When the switch 401 is OFF and the isolation port Piso is electrically detached from the ground, the power amplifier circuit 132 operates in a second mode (hereinafter may be referred to as Doherty mode).

FIG. 39 is a diagram illustrating exemplary load fluctuation characteristics of the power-added efficiency in the power amplifier circuit 132. Reading of FIG. 39 is substantially the same as that of FIG. 22.

Curves Cd and Cb indicate variations of the power-added efficiency which are obtained when the phase of the antenna 86a end is varied in Doherty mode and balance mode, respectively.

Curve Cr indicates variations of the power-added efficiency which are obtained when the phase of the antenna 86a end is varied in an amplifier circuit including an amplifier of the related art, such as a differential amplifier or a two-stage amplifier (hereinafter may be referred to as an amplifier circuit of the related art).

Curve Cr shows power-added efficiency close to 50 at or near a phase of 90°, but shows power-added efficiency of about 30 at or near a phase of 270°. Therefore, the amplifier circuit of the related art has a large amount of change of the power-added efficiency when the phase of the antenna 86a end fluctuates.

Curve Cb shows power-added efficiency of 35 or greater when the phase is varied by 360°, and shows that the range of fluctuation of the power-added efficiency is within about 3. Therefore, balance mode is a mode suitable for a specification which requires that fluctuation in the characteristics for the load impedance at the antenna 86a end be small.

Compared with curve Cb, curve Cd shows a slightly larger range of fluctuation of the power-added efficiency, but shows higher power-added efficiency at all the phases. Curve Cd shows a smaller range of fluctuation of the power-added efficiency than curve Cr. Therefore, Doherty mode is a mode suitable for a specification which requires excellent power-added efficiency while maintaining a constant range of fluctuation in the characteristics for the load impedance at the antenna 86a end.

In the present embodiment, the configuration of the power amplifier circuit 132, in which, in the power amplifier circuit 102, the resistive element 402 and the switch 401 are connected in series between the isolation port Piso of the 90° hybrid coupler 71 and the ground, is described. However, the configuration is not limited to this. A configuration, in which, in the power amplifier circuit 101, the resistive element 402 and the switch 401 are connected in series between the isolation port Piso of the 90° hybrid coupler 71 and the ground, may be employed.

### Seventh Embodiment

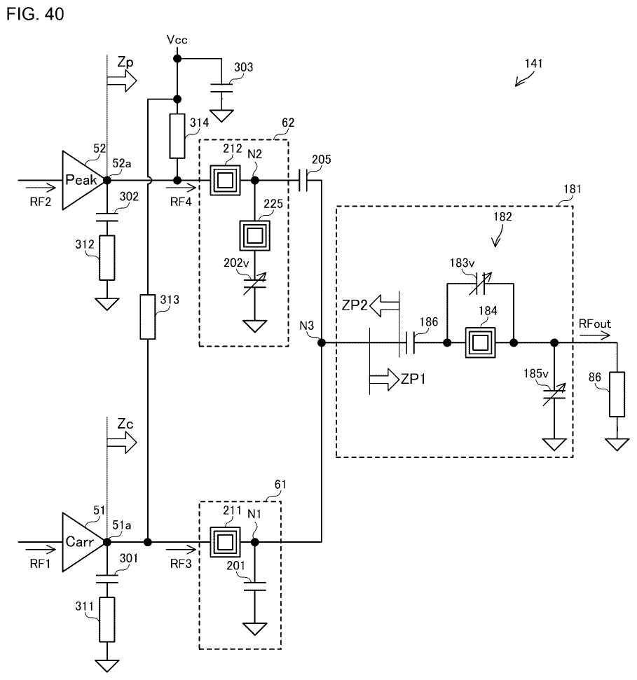

A power amplifier circuit 141 according to a seventh embodiment will be described. FIG. 40 is a circuit diagram of the power amplifier circuit 141. The power amplifier circuit 111 in FIG. 23 may have a difficulty in control of the load impedance of the carrier amplifier 51 and the peak amplifier 52 in the frequency band of the second harmonic in inverse class-F operation. Therefore, harmonic distortion characteristics may degrade.

In the present embodiment, the power amplifier circuit 141 is different from the power amplifier circuit 111 in FIG. 23 in the following points: the circuit configuration of the LC circuit 62; a point in which the inductor 215 is not disposed; and a point in which an LC circuit 181 is further included.

Compared with the LC circuit 62 in the power amplifier circuit 111, the LC circuit 62 in the power amplifier circuit 141 includes a capacitor 202v (second capacitor) instead of the capacitor 202, and further includes an inductor 225 (fifth inductor).

The inductor 212 in the power amplifier circuit 141 has its first end connected to the output terminal 52a of the peak amplifier 52, and its second end connected to the node N2.

The inductor 225 and the capacitor 202v are connected in series between the node N2 and the ground.

In the present embodiment, the inductor 225 has a first end connected to the node N2, and a second end connected to the ground through the capacitor 202v. The inductor 225 may be connected, at its first end, to the node N2 through the capacitor 202v, and may be grounded at its second end.

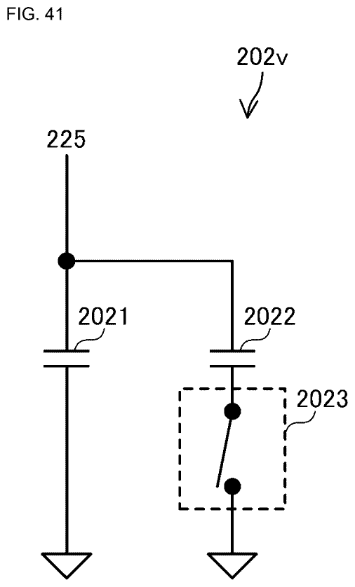

FIG. 41 is a diagram illustrating an exemplary capacitor 202v. As illustrated in FIG. 41, the electrostatic capacity of the capacitor 202v is variable. In the present embodiment, the capacitor 202v includes capacitors 2021 and 2022 and a switch 2023. For example, the electrostatic capacity of the capacitor 2021 is larger than that of the capacitor 2022.

The capacitor 2021 has a first end connected to the second end of the inductor 225, and a second end connected to the ground. The capacitor 2022 has a first end connected to the second end of the inductor 225, and a second end connected to the ground through the switch 2023. The capacitor 2022 may be connected, at its first end, to the second end of the inductor 225 through the switch 2023, and may be grounded at its second end.

The power amplifier circuit 141 may be used, for example, in the high frequency mode and the low frequency mode. The high frequency mode and the low frequency mode are suitable for amplification of input signals in a first frequency band and input signals in a second frequency band, respectively. The second frequency band is lower than the first frequency band. The first frequency band and the second frequency band are, for example, bands of approximately 0.7 to 0.9 GHz.

The switch 2023 is OFF in the high frequency mode, and is ON in the low frequency mode. That is, the electrostatic capacity of the capacitor 202v in the low frequency mode is larger than that in the high frequency mode.

As illustrated in FIG. 40, the capacitor 205 (third capacitor) has its first end connected to the node N2, and its second end connected to the node N1 through the node N3.

The LC circuit 181 is connected between the node N3 and the load 86. In detail, the LC circuit 181 includes a tank circuit 182, a capacitor 185v, and a capacitor 186. The tank circuit 182 includes a capacitor 183v (fifth capacitor) and an inductor 184 (sixth inductor).

The capacitor 186 in the LC circuit 181 has a first end connected to the node N3, and a second end. The capacitor 186 cuts DC components of an amplified signal obtained by combining the amplified signals RF3 and RF4 with each other.

The inductor 184 in the tank circuit 182 has a first end connected to the second end of the capacitor 186, and a second end connected to the ground through the load 86.

The capacitor 183v has a first end connected to the second end of the capacitor 186, and a second end connected to the second end of the inductor 184.

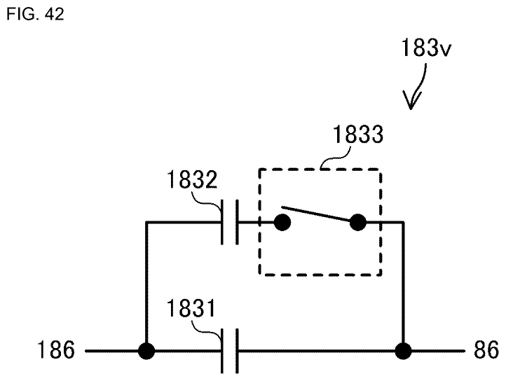

FIG. 42 is a diagram illustrating an exemplary capacitor 183v. As illustrated in FIG. 42, the electrostatic capacity of the capacitor 183v is variable. In the present embodiment, the capacitor 183v includes capacitors 1831 and 1832 and a switch 1833. For example, the electrostatic capacity of the capacitor 1831 is larger than that of the capacitor 1832.

The capacitor 1831 has a first end connected to the second end of the capacitor 186, and a second end connected to the second end of the inductor 184. The capacitor 1832 has a first end connected to the second end of the capacitor 186, and a second end connected to the second end of the inductor 184 through the switch 1833. The capacitor 1832 may be connected, at its first end, to the second end of the capacitor 186 through the switch 1833, and may be connected, at its second end, to the second end of the inductor 184.

The switch 1833 is OFF in the high frequency mode and is ON in the low frequency mode. That is, the electrostatic capacity of the capacitor 183v in the low frequency mode is larger than that in the high frequency mode.

As illustrated in FIG. 40, the capacitor 185v has a first end connected to the second end of the inductor 184, and a second end connected to the ground. The capacitor 185v converts the impedance.

The electrostatic capacity of the capacitor 185v is variable. In the present embodiment, the capacitor 185v has a configuration substantially the same as that of the capacitor 202v. The electrostatic capacity of the capacitor 185v in the low frequency mode is larger than that in the high frequency mode.

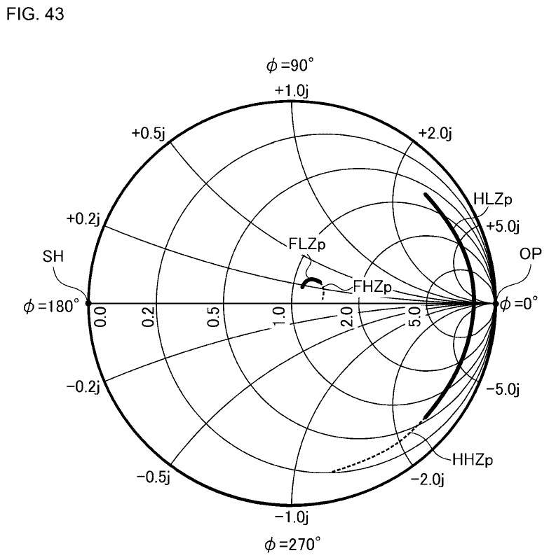

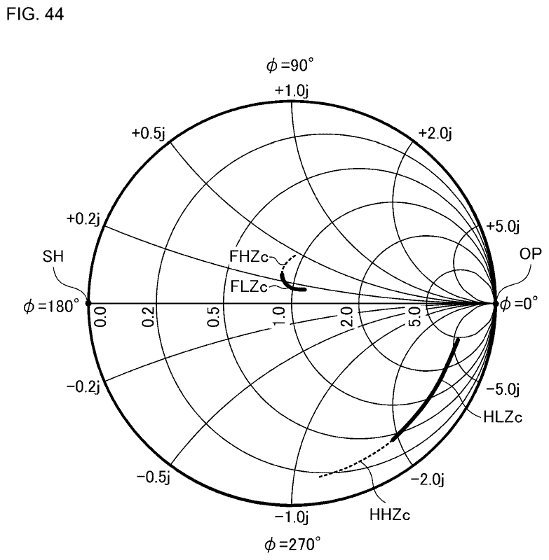

FIGS. 43 and 44 are diagrams illustrating Smith charts showing simulation results of variations in impedances Zp and Zc, respectively, relative to frequency variations in the power amplifier circuit 141.

FIG. 43 illustrates curves FHZp, FLZp, HHZp, and HLZp. Curves FHZp and FLZp show variations in impedance Zp for the fundamental in the first frequency band and the second frequency band, respectively. Curves HHZp and HLZp show variations in impedance Zp for the second harmonic based on the fundamental in the first frequency band and the second frequency band, respectively.

FIG. 44 illustrates curves FHZc, FLZc, HHZc, and HLZc. Curves FHZc and FLZc show variations in impedance Zc for the fundamental in the first frequency band and the second frequency band, respectively. Curves HHZc and HLZc show variations in impedance Zc for the second harmonic based on the fundamental in the first frequency band and the second frequency band, respectively.

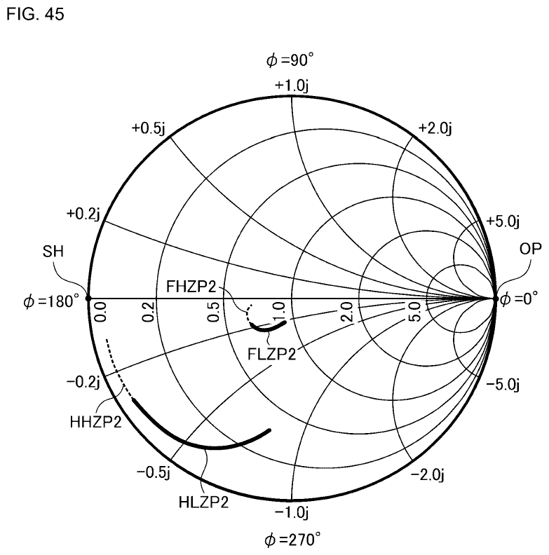

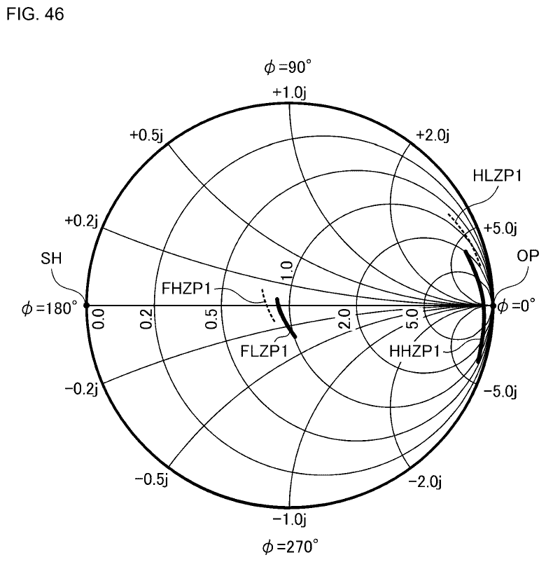

FIG. 45 is a diagram illustrating a Smith chart showing a simulation result of variations in impedance ZP2 relative to frequency variations in the power amplifier circuit 141. FIG. 45 illustrates curves FHZP2, FLZP2, HHZP2, and HLZP2. Curves FHZP2 and FLZP2 show variations in impedance ZP2 for the fundamental in the first frequency band and the second frequency band, respectively. Curves HHZP2 and HLZP2 show variations in impedance ZP2 for the second harmonic based on the fundamental in the first frequency band and the second frequency bands, respectively. Impedance ZP2 is impedance as seen from the capacitor 186 to the carrier amplifier 51 and the peak amplifier 52.

FIG. 46 is a diagram illustrating a Smith chart showing a simulation result of variations in impedance ZP1 relative to frequency variations in the power amplifier circuit 141. FIG. 46 illustrates curves FHZP1, FLZP1, HHZP1, and HLZP1. Curves FHZP1 and FLZP1 show variations in impedance ZP1 for the fundamental in the first frequency band and the second frequency band, respectively. Curves HHZP1 and HLZP1 show variations in impedance ZP1 for the second harmonic based on the fundamental in the first frequency band and the second frequency band, respectively. Impedance ZP1 is impedance as seen from the node N3 to the load 86.

As illustrated in FIGS. 43 and 44, curves FHZp, FLZp, FHZc, and FLZc are positioned near 1.0+0.0j. That is, control may be exerted so that impedance Zp and impedance Zc for the fundamental are comparable to the characteristic impedance.

Curves HHZp, HLZp, HHZc, and HLZc are positioned near the open OP. That is, control may be exerted so that the magnitudes of impedance Zp and impedance Zc for the second harmonic increase.

As illustrated in FIG. 45, the configuration, in which the LC circuit 62 further including the inductor 225 is disposed at the output of the peak amplifier 52 (see FIG. 40), causes curves HHZP2 and HLZP2 to be positioned near the short SH. That is, the magnitude of impedance ZP2 for the second harmonic is small.

In contrast, as illustrated in FIG. 46, the configuration, in which the tank circuit 182 is disposed between the node N3 and the load 86 (see FIG. 40), enables control to be exerted so that curves HHZP1 and HLZP1 are positioned near the open OP.

Thus, the difference between the phase of impedance ZP2 for the second harmonic and that of impedance ZP1 for the second harmonic may be set to approximately 180°. That is, for the second harmonic, the difference between the phase of traveling waves, which are transmitted from the carrier amplifier 51 and the peak amplifier 52 to the load 86, and the phase of reflected waves, which are obtained through reflection of the traveling waves and are transmitted to the carrier amplifier 51 and the peak amplifier 52, may be set to approximately 180°. This causes the traveling waves and the reflected waves of the second harmonic to cancel each other, achieving suppression of degradation of the harmonic distortion characteristics.

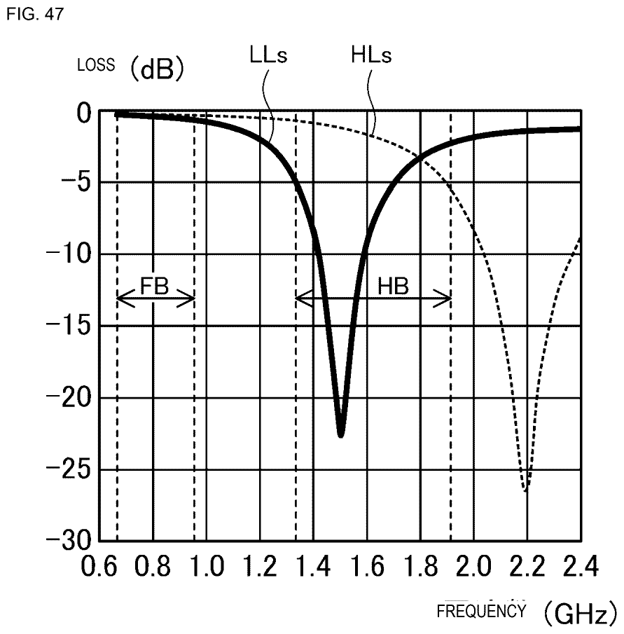

FIG. 47 is a diagram illustrating exemplary variations in loss relative to frequency variations in the LC circuit 181. The vertical axis indicates loss whose unit is “dBm”. The horizontal axis indicates frequency whose unit is “GHz”.

FIG. 47 illustrates curves LLs and HLs. Curve LLS shows variations in loss relative to frequency variations when a signal passes through the LC circuit 181 in the case where the capacitor 185v has an electrostatic capacity of the low frequency mode.

Curve HLs shows variations in loss relative to frequency variations when a signal passes through the LC circuit 181 in the case where the capacitor 185v has an electrostatic capacity of the high frequency mode.

As illustrated in FIG. 47, in the fundamental band FB, mainly by switching the capacitor 185v, occurrence of loss caused when fundamental waves pass through the LC circuit 181 may be suppressed both in the high frequency mode and in the low frequency mode.

In the second harmonic band HB, mainly by switching the capacitor 183v, the second harmonic waves based on the fundamental waves may be attenuated excellently both in the high frequency mode and in the low frequency mode.

The configuration, in which the capacitors 183v and 185v enable switching between the low frequency mode and the high frequency mode, achieves excellent attenuation of the second harmonic based on the fundamental while degradation of the bandpass characteristics of the fundamental is suppressed in a broad frequency band.

In the present embodiment, the configuration, in which the electrostatic capacities of the capacitors 183v, 185v, and 202v are variable, is described. However, the configuration is not limited to this. At least one of the electrostatic capacities of the capacitors 183v, 185v, and 202v may be fixed.

The exemplary embodiments of the present disclosure are described above. In the power amplifier circuits 101 and 111, the carrier amplifier 51 amplifies the signal RF1, and outputs the amplified signal RF3 from the output terminal 51a. The peak amplifier 52 amplifies the signal RF2 different in phase from the signal RF1, and outputs the amplified signal RF4 from the output terminal 52a. The inductor 211 has its first end connected to the output terminal 51a, and its second end connected to the node N1. The capacitor 201 has its first end connected to the node N1, and its second end connected to the ground. The inductor 212 has its first end connected to the output terminal 52a, and its second end connected to the node N2. The capacitor 202 has its first end connected to the node N2, and its second end connected to the ground. The inductors 213 and 215 each has its first end connected to the node N1, and its second end connected to the node N3 connected to the load 86. The capacitors 203 and 205 each have its first end connected to the node N2, and its second end connected to the node N3.

A configuration, in which the inductors 211 and 212 and the capacitors 201 and 202 are not disposed, has a difficulty in adjustment of the phase difference between the signals and the change in phase across the output terminals. As described above, the configuration in which the inductor 211 series-connected between the output terminal 51a and the node N1, the capacitor 201 shunt-connected to the node N1, the inductor 212 series-connected between the output terminal 52a and the node N2, and the capacitor 202 shunt-connected to the node N2 are disposed, achieves adequate adjustment of the phase difference between the signals and the change in phase across the output terminals. Thus, operation close to that of a Doherty amplifier circuit may be implemented, achieving enhancement of the power-added efficiency and suppression of variations of the power-added efficiency relative to fluctuations in the load impedance. In addition, since no quarter-wave lines are used, the circuit sizes of the power amplifier circuits 101 and 111 may be decreased. Therefore, a power amplifier circuit, which enables a reduction in size, high efficiency, and high resistance to fluctuations in the load impedance to be achieved, may be provided.

In the power amplifier circuit 101, the carrier amplifier 51 amplifies the signal RF1, and outputs the amplified signal RF3 from the output terminal 51a. The peak amplifier 52 amplifies the signal RF2 different in phase from the signal RF1, and outputs the amplified signal RF4 from the output terminal 52a. The inductor 211 has its first end connected to the output terminal 51a, and its second end connected to the node N1. The capacitor 201 has its first end connected to the node N1, and its second end connected to the ground. The inductor 212 has its first end connected to the output terminal 52a, and its second end connected to the node N2. The capacitor 202 has its first end connected to the node N2, and its second end connected to the ground. The 90° hybrid coupler 71 has the input port Pin1, which is connected to the node N1 and which is supplied with the amplified signal RF3, the input port Pin2, which is connected to the node N2 and which is supplied with the amplified signal RF4, the output port Pout, which is connected to the node N3 connected to the load 86 and from which the output signal RFout is outputted, and the isolation port Piso.

A configuration, in which the inductors 211 and 212 and the capacitors 201 and 202 are not disposed, has a difficulty in adjustment of the phase difference between the signals and the change in phase across the output terminals. As described above, the configuration, in which the inductor 211 series-connected between the output terminal 51a and the node N1, the capacitor 201 shunt-connected to the node N1, the inductor 212 series-connected between the output terminal 52a and the node N2, and the capacitor 202 shunt-connected to the node N2 are disposed, achieves adequate adjustment of the phase difference between the signals and the change in phase across the output terminals. Thus, operation close to that of a Doherty amplifier circuit may be implemented, achieving enhancement of the power-added efficiency and suppression of variations of the power-added efficiency relative to fluctuations in the load impedance. In addition, since no quarter-wave lines are used, the circuit size of the power amplifier circuit 101 may be decreased. Therefore, a power amplifier circuit, which enables a reduction in size, high efficiency, and high resistance to fluctuations in the load impedance to be achieved, may be provided. In addition, since the isolation port Piso is not connected to any terminator, output matching loss caused by a terminator may be suppressed. Use of the 90° hybrid coupler 71 achieves enhancement of accuracy of adjustment of the phase difference between the signals and the change in phase across the output terminals.

In the power amplifier circuits 102 and 112, the carrier amplifier 51 amplifies the signal RF1, and outputs the amplified signal RF3 from the output terminal 51a. The peak amplifier 52 amplifies the signal RF2 different in phase from the signal RF1, and outputs the amplified signal RF4 from the output terminal 52a. The capacitor 201 has its first end connected to the output terminal 51a, and its second end connected to the node N1. The inductor 211 has its first end connected to the node N1, and its second end connected to the ground. The capacitor 202 has its first end connected to the output terminal 52a, and its second end connected to the node N2. The inductor 212 has its first end connected to the node N2, and its second end connected to the ground. The capacitors 203 and 205 each have its first end connected to the node N1, and its second end connected to the node N3 connected to the load 86. The inductors 213 and 215 each has its first end connected to the node N2, and its second end connected to the node N3.

A configuration, in which the inductors 211 and 212 and the capacitors 201 and 202 are not disposed, has a difficulty in adjustment of the phase difference between the signals and the change in phase across the output terminals. As described above, the configuration, in which the capacitor 201 series-connected between the output terminal 51a and the node N1, the inductor 211 shunt-connected to the node N1, the capacitor 202 series-connected between the output terminal 52a and the node N2, and the inductor 212 shunt-connected to the node N2 are disposed, achieves adequate adjustment of the phase difference between the signals and the change in phase across the output terminals. Thus, operation close to that of a Doherty amplifier circuit may be implemented, achieving enhancement of the power-added efficiency and suppression of variations of the power-added efficiency relative to fluctuations in the load impedance. In addition, since no quarter-wave lines are used, the circuit sizes of the power amplifier circuits 102 and 112 may be decreased. Therefore, a power amplifier circuit, which enables a reduction in size, high efficiency, and high resistance to fluctuations in the load impedance to be achieved, may be provided.

In the power amplifier circuit 102, the carrier amplifier 51 amplifies the signal RF1, and outputs the amplified signal RF3 from the output terminal 51a. The peak amplifier 52 amplifies the signal RF2 different in phase from the signal RF1, and outputs the amplified signal RF4 from the output terminal 52a. The capacitor 201 has its first end connected to the output terminal 51a, and its second end connected to the node N1. The inductor 211 has its first end connected to the node N1, and its second end connected to the ground. The capacitor 202 has its first end connected to the output terminal 52a, and its second end connected to the node N2. The inductor 212 has its first end connected to the node N2, and its second end connected to the ground. The 90° hybrid coupler 71 has the input port Pin1, which is connected to the node N1 and which is supplied with the amplified signal RF3, the input port Pin2, which is connected to the node N2 and which is supplied with the amplified signal RF4, the output port Pout, which is connected to the node N3 connected to the ground through the load 86 and from which the output signal RFout is outputted, and the isolation port Piso.

A configuration, in which the inductors 211 and 212 and the capacitors 201 and 202 are not disposed, has a difficulty in adjustment of the phase difference between the signals and the change in phase across the output terminals. As described above, the configuration, in which the capacitor 201 series-connected between the output terminal 51a and the node N1, the inductor 211 shunt-connected to the node N1, the capacitor 202 series-connected between the output terminal 52a and the node N2, and the inductor 212 shunt-connected to the node N2 are disposed, achieves adequate adjustment of the phase difference between the signals and the change in phase across the output terminals. Thus, operation close to that of a Doherty amplifier circuit may be implemented, achieving enhancement of the power-added efficiency and suppression of variations of the power-added efficiency relative to fluctuations in the load impedance. In addition, since no quarter-wave lines are used, the circuit size of the power amplifier circuit 102 may be decreased. Therefore, a power amplifier circuit, which enables a reduction in size, high efficiency, and high resistance to fluctuations in the load impedance to be achieved, may be provided. In addition, since the isolation port Piso is not connected to any terminator, output matching loss caused by a terminator may be suppressed. Use of the 90° hybrid coupler 71 achieves enhancement of accuracy of adjustment of the phase difference between the signals and the change in phase across the output terminals.

In the power amplifier circuit 101, the capacitor 204 has its first end connected to the node N1, and its second end which is the isolation port Piso. The inductor 214 has its first end connected to the node N2, and its second end connected to the second end of the capacitor 204. The inductor 213 is electromagnetically coupled to the inductor 214.

Such a configuration enables the 90° hybrid coupler 71 to be implemented by using the capacitors 203 and 204 and the inductors 213 and 214 without necessarily use of a quarter-wave line, achieving a reduction in circuit size of the power amplifier circuit 101. Implementation of the 90° hybrid coupler 71 achieves enhancement of accuracy of adjustment of the phase difference between the signals and the change in phase across the output terminals.

In the power amplifier circuit 102, the capacitor 204 has its first end connected to the node N2, and its second end which is the isolation port Piso. The inductor 214 has its first end connected to the node N1, and its second end connected to the second end of the capacitor 204. The inductor 213 is electromagnetically coupled to the inductor 214.

Such a configuration enables the 90° hybrid coupler 71 to be implemented by using the capacitors 203 and 204 and the inductors 213 and 214 without use of a quarter-wave line, achieving a reduction in circuit size of the power amplifier circuit 102. Implementation of the 90° hybrid coupler 71 achieves enhancement of accuracy of adjustment of the phase difference between the signals and the change in phase across the output terminals.

In the power amplifier circuits 101, 102, 111, and 112, the magnitude of the difference between the change in phase, which is obtained when the amplified signal RF3 outputted from the output terminal 51a passes through the node N1, the node N3, and the load 86, and the change in phase, which is obtained when the amplified signal RF4 outputted from the output terminal 52a passes through the node N2, the node N3, and the load 86, is greater than or equal to 60° and less than or equal to 120°.

With a circuit size smaller than that of the power amplifier circuit 900 which is a Doherty amplifier circuit of the related art and which has the quarter-wave line 42, such a configuration enables the phase difference between the signals in the power amplifier circuits 101, 102, 111, and 112 to be equivalent to that of the power amplifier circuit 900.

In the power amplifier circuits 101, 102, 111, and 112, the magnitude of the change in phase of the amplified signal RF3 is greater than or equal to 45° and less than or equal to 135° when the amplified signal RF3 passes from the output terminal 51a through the nodes N1 and N2 to the output terminal 52a.

With a circuit size smaller than that of the power amplifier circuit 900 which is a Doherty amplifier circuit of the related art and which has the quarter-wave line 42, such a configuration enables the change in phase across the output terminals in the power amplifier circuits 101, 102, 111, and 112 to be equivalent to that of the power amplifier circuit 900.

In the power amplifier circuit 122, each of the capacities of the capacitor 203v and the capacitor 204v is variable.

Thus, adjustment of the capacities of the capacitor 203v and the capacitor 204v enables the frequency characteristics of the change in phase across the output terminals in the power amplifier circuit 122 to be changed. Specifically, appropriate adjustment of the capacities of the capacitor 203v and the capacitor 204v in accordance with the frequency band of the signals RF1 and RF2 enables optimal change in phase across the output terminals to be achieved in the frequency band. Thus, the power amplifier circuit 122 may operate excellently in a wide band.

In the power amplifier circuit 132, the switch 401 and the resistive element 402 are connected in series between the isolation port Piso and the ground.

Such a configuration enables operation as a balanced amplifier to be performed by switching on the switch 401. Thus, the power amplifier circuit 132 may operate in the balance mode suitable for a specification which requires that fluctuations in the characteristics for the impedance of the load at the antenna 86a end be small. Switching off the switch 401 enables operation as an amplifier circuit equivalent to the power amplifier circuit 102 to be performed. Thus, the power amplifier circuit 132 may operate in the Doherty mode suitable for a specification which requires excellent power-added efficiency.

In the power amplifier circuit 141, the carrier amplifier 51 amplifies the signal RF1, and outputs the amplified signal RF3 from the output terminal 51a. The peak amplifier 52 amplifies the signal RF2 different in phase from the signal RF1, and outputs the amplified signal RF4 from the output terminal 52a. The inductor 211 has its first end connected to the output terminal 51a, and its second end connected to the node N1 connected to the load 86. The capacitor 201 has its first end connected to the node N1, and its second end connected to the ground. The inductor 212 has its first end connected to the output terminal 52a, and its second end connected to the node N2. The capacitor 205 has its first end connected to the node N2, and its second end connected to the node N1. The inductor 225 and the capacitor 202v are connected in series between the node N2 and the ground.

Thus, the configuration, in which the inductor 225 and the capacitor 202v are connected in series between the node N2 and the ground, enables impedance Zp and impedance Zc for the second harmonic based on the fundamental to be made close to the open OP. Thus, the power of the second harmonic which is outputted to the load 86 side may be reduced, achieving suppression of degradation of the harmonic distortion characteristics. A configuration, in which the inductors 211, 212, and 225 and the capacitors 201 and 202v are not disposed, has a difficulty in adjustment of the phase difference between the signals and the change in phase across the output terminals. As described above, the configuration, in which the inductor 211 series-connected between the output terminal 51a and the node N1, the capacitor 201 shunt-connected to the node N1, the inductor 212 series-connected between the output terminal 52a and the node N2, and the inductor 225 and the capacitor 202v connected in series between the node N2 and the ground are disposed, achieves adequate adjustment of the phase difference between the signals and the change in phase across the output terminals. Thus, operation close to that of a Doherty amplifier circuit may be implemented, achieving enhancement of the power-added efficiency and suppression of variations of the power-added efficiency relative to fluctuations in the load impedance. In addition, since no quarter-wave lines are used, the circuit size of the power amplifier circuit 141 may be decreased. Further, the configuration, in which the inductor 215 in the power amplifier circuit 111 (see FIG. 23) is not disposed in the power amplifier circuit 141, achieves a further smaller circuit size of the power amplifier circuit 141. Therefore, a power amplifier circuit, which enables a reduction in size, high efficiency, and high resistance to fluctuations in the load impedance to be achieved, may be provided.

In the power amplifier circuit 141, the inductor 184 has its first end connected to the node N1, and its second end connected to the load 86. The capacitor 183v has its first end connected to the first end of the inductor 184, and its second end connected to the second end of the inductor 184.

Impedance ZP2 as seen from the capacitor 186 to the carrier amplifier 51 and the peak amplifier 52 is positioned near the short SH because of arrangement of the LC circuit 62 including the inductor 225. The configuration described above enables impedance ZP1 as seen from the node N3 to the load 86 to be made close to the open OP, and enables the difference between the phase of impedance ZP2 for the second harmonic and that of impedance ZP1 for the second harmonic to be set to approximately 180°. Thus, degradation of the harmonic distortion characteristics may be suppressed.

In the power amplifier circuit 141, the electrostatic capacity of the capacitor 202v is variable.

Thus, the configuration, in which the resonant frequency of the inductor 225 and the capacitor 202v may be varied through variations of the electrostatic capacity of the capacitor 202v, achieves a wider frequency band in which the second harmonic based on the fundamental is attenuated excellently while degradation of the bandpass characteristics of the fundamental is suppressed.

In the power amplifier circuit 141, the electrostatic capacity of the capacitor 183v is variable.

Thus, the configuration, in which the resonant frequency of the inductor 184 and the capacitor 183v may be varied through variations of the electrostatic capacity of the capacitor 183v, achieves a wider frequency band in which the second harmonic based on the fundamental is attenuated excellently while degradation of the bandpass characteristics of the fundamental is suppressed.

The embodiments are described above to facilitate understanding of the present disclosure, not to limit the interpretation of the present disclosure. The present disclosure may be changed/improved without departing from its gist, and encompasses its equivalents. That is, embodiments obtained by those skilled in the art appropriately changing the design of the embodiments are encompassed in the scope of the present disclosure as long as they have features of the present disclosure. For example, the components included in the embodiments, and their arrangement, materials, conditions, shapes, sizes, and the like are not limited to the illustrated ones, and may be changed appropriately. Needless to say, the embodiments are exemplary, and partial replacement or combination of configurations in different embodiments may be made. These are encompassed in the scope of the present disclosure as long as these have features of the present disclosure.

<1>

A power amplifier circuit comprising:
a carrier amplifier that amplifies a first signal, and that outputs a first amplified signal from a first output terminal;
a peak amplifier that amplifies a second signal different in phase from the first signal, and that outputs a second amplified signal from a second output terminal;
a first inductor that has a first end connected to the first output terminal, and a second end connected to a first node;
a first capacitor that has a first end connected to the first node, and a second end connected to a ground;
a second inductor that has a first end connected to the second output terminal, and a second end connected to a second node;
a second capacitor that has a first end connected to the second node, and a second end connected to the ground;
a third inductor that has a first end connected to the first node, and a second end connected to a third node connected to a load; and
a third capacitor that has a first end connected to the second node, and a second end connected to the third node.
   <2>

A power amplifier circuit comprising:
a carrier amplifier that amplifies a first signal, and that outputs a first amplified signal from a first output terminal;
a peak amplifier that amplifies a second signal different in phase from the first signal, and that outputs a second amplified signal from a second output terminal;
a first inductor that has a first end connected to the first output terminal, and a second end connected to a first node;
a first capacitor that has a first end connected to the first node, and a second end connected to a ground;
a second inductor that has a first end connected to the second output terminal, and a second end connected to a second node;
a second capacitor that has a first end connected to the second node, and a second end connected to the ground; and
a 90° hybrid coupler that has a first input port, a second input port, an output port, and an isolation port, the first input port being connected to the first node and being supplied with the first amplified signal, the second input port being connected to the second node and being supplied with the second amplified signal, the output port being connected to a third node connected to a load and being a port from which an output signal is outputted.
   <3>

A power amplifier circuit comprising:
a carrier amplifier that amplifies a first signal, and that outputs a first amplified signal from a first output terminal;
a peak amplifier that amplifies a second signal different in phase from the first signal, and that outputs a second amplified signal from a second output terminal;
a first capacitor that has a first end connected to the first output terminal, and a second end connected to a first node;
a first inductor that has a first end connected to the first node, and a second end connected to a ground;
a second capacitor that has a first end connected to the second output terminal, and a second end connected to a second node;
a second inductor that has a first end connected to the second node, and a second end connected to the ground;
a third capacitor that has a first end connected to the first node, and a second end connected to a third node connected to a load; and
a third inductor that has a first end connected to the second node, and a second end connected to the third node.
   <4>

A power amplifier circuit comprising:
a carrier amplifier that amplifies a first signal, and that outputs a first amplified signal from a first output terminal;
a peak amplifier that amplifies a second signal different in phase from the first signal, and that outputs a second amplified signal from a second output terminal;
a first capacitor that has a first end connected to the first output terminal, and a second end connected to a first node;
a first inductor that has a first end connected to the first node, and a second end connected to a ground;
a second capacitor that has a first end connected to the second output terminal, and a second end connected to a second node;
a second inductor that has a first end connected to the second node, and a second end connected to the ground; and
a 90° hybrid coupler that has a first input port, a second input port, an output port, and an isolation port, the first input port being connected to the first node and being supplied with the first amplified signal, the second input port being connected to the second node and being supplied with the second amplified signal, the output port being connected to a third node connected to a load and being a port from which an output signal is outputted.
   <5>

The power amplifier circuit according to <1>, further comprising:
a fourth capacitor that has a first end connected to the first node, and a second end which is an isolation port; and
a fourth inductor that has a first end connected to the second node, and a second end connected to the second end of the fourth capacitor,
wherein the third inductor is electromagnetically coupled to the fourth inductor.
   <6>

The power amplifier circuit according to <3>, further comprising:
a fourth capacitor that has a first end connected to the second node, and a second end which is an isolation port; and
a fourth inductor that has a first end connected to the first node, and a second end connected to the second end of the fourth capacitor,
wherein the third inductor is electromagnetically coupled to the fourth inductor.
   <7>

The power amplifier circuit according to any one of <1> to <6>,
wherein a magnitude of a difference between a change in phase of the first amplified signal and a change in phase of the second amplified signal is greater than or equal to 60° and less than or equal to 120°, the change in phase of the first amplified signal being obtained when the first amplified signal outputted from the first output terminal passes through the first node, the third node, and the load, the change in phase of the second amplified signal being obtained when the second amplified signal outputted from the second output terminal passes through the second node, the third node, and the load.
   <8>

The power amplifier circuit according to any one of <1> to <7>,
wherein a magnitude of a change in phase of the first amplified signal is greater than or equal to 45° and less than or equal to 135° when the first amplified signal passes from the first output terminal through the first node and the second node to the second output terminal.
   <9>

The power amplifier circuit according to <5> or <6>,
wherein each of a capacity of the third capacitor and a capacity of the fourth capacitor is variable.
   <10>

The power amplifier circuit according to <2>, <4>, <5> or <6>, further comprising:
a resistive element and a switch that are connected in series between the isolation port and the ground.
   <11>

A power amplifier circuit comprising:
a carrier amplifier that amplifies a first signal, and that outputs a first amplified signal from a first output terminal;
a peak amplifier that amplifies a second signal different in phase from the first signal, and that outputs a second amplified signal from a second output terminal;
a first inductor that has a first end connected to the first output terminal, and a second end connected to a first node connected to a load;
a first capacitor that has a first end connected to the first node, and a second end connected to a ground;
a second inductor that has a first end connected to the second output terminal, and a second end connected to a second node;
a third capacitor that has a first end connected to the second node, and a second end connected to the first node; and
a fifth inductor and a second capacitor that are connected in series between the second node and the ground.
   <12>

The power amplifier circuit according to <11>, further comprising:
a sixth inductor that has a first end connected to the first node, and a second end connected to the load; and
a fifth capacitor that has a first end connected to the first end of the sixth inductor, and a second end connected to the second end of the sixth inductor.
   <13>

The power amplifier circuit according to <11> or <12>,
wherein an electrostatic capacity of the second capacitor is variable.
   <14>

The power amplifier circuit according to <12>,
wherein an electrostatic capacity of the fifth capacitor is variable.

### REFERENCE SIGNS LIST

42 quarter-wave line
51 carrier amplifier
51a output terminal
52 peak amplifier
52a output terminal
61, 62 LC circuit
71, 72 90° hybrid coupler
81 LC circuit
82 inductor
83 capacitor
86 load
86a antenna
101, 102, 111, 112, 122, 132, 141, 900, 901, 902, 903 power amplifier circuit
171, 172, 181 LC circuit
182 tank circuit
183v, 185v, 186 capacitor
1831, 1832 capacitor
1833 switch
184 inductor
201, 202, 202v, 203, 203v, 204, 204v, 205 capacitor
2021, 2022 capacitor
2023 switch
211, 212, 213, 214, 215, 225 inductor
301, 302, 303 capacitor
311, 312, 313, 314 line
315 inductor
401 switch
402 resistive element
N1, N2, N3 node
Pin1, Pin2 input port
Pout output port
Piso isolation port

1. A power amplifier circuit comprising:
a carrier amplifier configured to amplify a first signal, and output a first amplified signal from a first output terminal;
a peak amplifier configured to amplify a second signal different in phase from the first signal, and output a second amplified signal from a second output terminal;
a first inductor having a first end connected to the first output terminal, and a second end connected to a first node;
a first capacitor having a first end connected to the first node, and a second end connected to ground;
a second inductor having a first end connected to the second output terminal, and a second end connected to a second node;
a second capacitor having a first end connected to the second node, and a second end connected to ground;
a third inductor having a first end connected to the first node, and a second end connected to a load via a third node; and
a third capacitor having a first end connected to the second node, and a second end connected to the third node.

2. A power amplifier circuit comprising:
a carrier amplifier configured to amplify a first signal, and output a first amplified signal from a first output terminal;
a peak amplifier configured to amplify a second signal different in phase from the first signal, and output a second amplified signal from a second output terminal;
a first inductor having a first end connected to the first output terminal, and a second end connected to a first node;
a first capacitor having a first end connected to the first node, and a second end connected to ground;
a second inductor having a first end connected to the second output terminal, and a second end connected to a second node;
a second capacitor having a first end connected to the second node, and a second end connected to ground; and
a 90° hybrid coupler having a first input port, a second input port, an output port, and an isolation port, the first input port being connected to the first node and being supplied with the first amplified signal, the second input port being connected to the second node and being supplied with the second amplified signal, the output port being configured to output an output signal and connected to a load via a third node.

3. The power amplifier circuit according to claim 1, further comprising:
a fourth capacitor having a first end connected to the first node, and a second end as an isolation port; and
a fourth inductor having a first end connected to the second node, and a second end connected to the second end of the fourth capacitor,
wherein the third inductor is electromagnetically coupled to the fourth inductor.

4. The power amplifier circuit according to claim 1,
wherein a magnitude of a difference between a change in phase of the first amplified signal and a change in phase of the second amplified signal is greater than or equal to 60° and less than or equal to 120° when the first amplified signal passes through the first node, the third node, and the load, and the second amplified signal passes through the second node, the third node, and the load.

5. The power amplifier circuit according to claim 2,
wherein a magnitude of a difference between a change in phase of the first amplified signal and a change in phase of the second amplified signal is greater than or equal to 60° and less than or equal to 120° when the first amplified signal passes through the first node, the third node, and the load, and the second amplified signal passes through the second node, the third node, and the load.

6. The power amplifier circuit according to claim 1,
wherein a magnitude of a change in phase of the first amplified signal is greater than or equal to 45° and less than or equal to 135° when the first amplified signal passes from the first output terminal through the first node and the second node to the second output terminal.

7. The power amplifier circuit according to claim 2,
wherein a magnitude of a change in phase of the first amplified signal is greater than or equal to 45° and less than or equal to 135° when the first amplified signal passes from the first output terminal through the first node and the second node to the second output terminal.

8. The power amplifier circuit according to claim 3,
wherein the third capacitor and the fourth capacitor are variable capacitors.

9. The power amplifier circuit according to claim 2, further comprising:
a resistive circuit element and a switch connected in series between the isolation port and the ground.

10. A power amplifier circuit comprising:
a carrier amplifier configured to amplify a first signal, and output a first amplified signal from a first output terminal;
a peak amplifier configured to amplify a second signal different in phase from the first signal, and output a second amplified signal from a second output terminal;
a first inductor having a first end connected to the first output terminal, and a second end connected to a load via a first node;
a first capacitor having a first end connected to the first node, and a second end connected to ground;
a second inductor having a first end connected to the second output terminal, and a second end connected to a second node;
a third capacitor having a first end connected to the second node, and a second end connected to the first node; and
a fifth inductor and a second capacitor connected in series between the second node and ground.

11. The power amplifier circuit according to claim 10, further comprising:
a sixth inductor having a first end connected to the first node, and a second end connected to the load; and
a fifth capacitor having a first end connected to the first end of the sixth inductor, and a second end connected to the second end of the sixth inductor.

12. The power amplifier circuit according to claim 10,
wherein the second capacitor is a variable capacitor.

13. The power amplifier circuit according to claim 11,
wherein the fifth capacitor is a variable capacitor.
